(19) United States
(12) Patent Application Publication
(10) Pub. No.: US 2022/0293390 A1
(43) Pub. Date: Sep. 15, 2022

(54) E-BEAM POSITION TRACKER

(71) Applicant: Nikon Corporation, Tokyo (JP)

(72) Inventors: Jacek Kazimierz Tyminski, Mountain View, CA (US); Daniel Gene Smith, Tucson, AZ (US); Steven Douglas Slonaker, San Mateo, CA (US); Stephen Paul Renwick, Moss Beach, CA (US); Johnathan Agustin Marquez, San Francisco, CA (US)

(21) Appl. No.: 17/654,707

(22) Filed: Mar. 14, 2022

Related U.S. Application Data
(60) Provisional application No. 63/160,650, filed on Mar. 12, 2021.

(51) Int. Cl. H01J 37/244; H01J 37/20; B33Y 30/00

(52) U.S. Cl. CPC H01J 37/244; H01J 37/20; B33Y 30/00; H01J 2237/24578; H01J 2237/0453; H01J 2237/20221

(57) ABSTRACT

Electron beam position, size, or shape can be estimated by deflecting the beam to a plurality of apertures, either continuously or step-wise. Beam portions transmitted, absorbed, or scattered can be used to assess position, size, and shape. In other examples, a beam sensing aperture and the beam are oscillated with respect to each other by moving the aperture or varying the beam deflection or both. The beam can be directed to segmented detectors such as a quad detector, and currents in the segments used to assess beam position, shape, or size. The segments can be formed from a single conductive sheet on which the segments are defined but remain attached. After the conductive sheet is secured with an insulative adhesive, portions of the conductive sheet are broken away, leaving aligned segments.

### CROSS-REFERENCE TO RELATED APPLICATIONS

This application claims the benefit of U.S. Provisional Application 63/160,650, filed Mar. 12, 2021, which is incorporated herein by reference.

### FIELD

The disclosure pertains to scan correction for charged-particle-beam systems.

### BACKGROUND

Electron beam systems have been developed for use in additive manufacturing and many other measurement and processing applications. In these systems, an electron beam must be accurately directed to a target in order to produce the intended results. In addition, systems that use high power electron beams must be aligned so that the electron beam does not damage electron optical components or accidently irradiate working surfaces in unwanted locations. While electron beam systems can be aligned manually by a technician, this can be complex, lengthy, and expensive. Manual approaches can be subjective so that alignment varies depending on which technician does the alignment. For these and other reasons, improved approaches are needed.

### SUMMARY

Aperture assemblies for use with charged particle beams (CPBs) include a charged-particle-beam (CPB) trap and a conductive layer containing a plurality of apertures. An insulator layer is fixed between the conductive layer and the CPB trap, the insulator layer defining a least one aperture corresponding to the plurality of apertures; the assemblage is sometimes called a Faraday cup. In other examples, the conductive layer is spaced apart. In some examples, the insulator layer is a ring-shaped insulator layer having a central aperture, wherein the central aperture has a diameter such that each of the plurality of apertures of the conductive layer terminates at the central aperture. In some embodiments, each of the plurality of apertures of the conductive layer tapers so as to narrow from an exterior surface to an interior surface adjacent the insulator layer. In typical examples, the insulator layer includes a plurality of apertures each corresponding to a respective aperture in the conductive layer and each of the plurality of apertures of the insulator layer tapers so as to widen from an outer surface adjacent the interior surface of the conductive layer surface to the trap. In some examples, the apertures of the insulator layer and the conductive layer have frustoconical tapers and the apertures in the conductive layer are arranged in a rectangular array.

Methods comprise sequentially deflecting a charged-particle beam (CPB) to each aperture of a plurality of apertures and recording deflection values associated with each aperture. In some embodiments, the deflecting the CPB to each aperture comprises directing the CPB to at least one aperture of the plurality of apertures with a first beam focus and then directing the CPB to each aperture with a second beam focus, wherein the deflection values associated with the second beam focus are the recorded deflection values and wherein a beam size at the plurality of apertures is larger with the first beam focus than the second beam focus. In typical examples, one or more of the recorded deflection values is applied to process a substrate by additive manufacturing, probe a substrate, or otherwise use the recorded deflection values as applied to the CPB. In further examples, CPB deflections are adjusted to obtain CPB deflection values corresponding to locations of each of the apertures based on one or more of a reflected CPB current, a transmitted CPB current, a secondary CPB current, or a scattered CPB current associated with each aperture. In further examples, CPB deflection values for locations between the apertures are determined based on the recorded adjusted CPB deflection values using interpolation with the recorded adjusted CPB deflection values. In representative examples, an image of an aperture plate defining the plurality of apertures is obtained by deflecting the CPB toward each of the apertures based on original CPB deflection values and cathodoluminescence associated with each of the initial deflections in response to the CPB. Initial CPB deflection values are based on the original CPB deflection values and locations associated with the cathodoluminescence associated with each original CPB deflection value. In some examples, a cathodoluminescence image of an unpatterned target and an image of an aperture plate are used to establish aperture coordinates.

Apparatus comprise an aperture plate defining a beam sensing aperture that is transmissive to a charged particle beam (CPB) and at least one actuator coupled to the beam sensing aperture. An actuator driver is coupled to the at least one actuator and operable to oscillate the aperture plate to periodically attenuate the CPB with the beam sensing aperture. A position analyzer is situated to receive a signal associated with the periodic attenuation of the CPB by the beam sensing aperture, and, based on the received signal and the oscillation of the aperture plate, provide an estimate of the CPB position, size, and/or shape at the aperture plate in at least one dimension. In some examples, the signal associated with the periodic attenuation is based one or more portions of the CPB transmitted, reflected, or scattered by the aperture plate or secondary emission responsive to the portions of the CPB transmitted, reflected, or scattered by the aperture plate. In typical examples, the actuator includes a first piezoelectric actuator and a second piezoelectric actuator operable to oscillate the aperture plate periodically in different directions, and the position analyzer provides the estimate of the CPB position at the aperture plate in two dimensions. In further examples, a stage is coupled to the beam sensing aperture, wherein the stage is operable to translate the beam sensing aperture to a plurality of beam sampling locations and the actuator driver is coupled to the at least one actuator to oscillate the beam sensing aperture plate to periodically attenuate the CPB at each of the beam sampling locations. The position analyzer is configured to provide estimates of the CPB position at each of the beam sampling locations.

In other examples, apparatus include an aperture plate defining a beam sensing aperture that is transmissive to a charged particle beam (CPB) and a position analyzer is situated to receive a signal associated with a periodic attenuation of the CPB by the beam sensing aperture, and, based on the received signal, provide an estimate of the CPB position at the aperture plate in at least one dimension. In some examples, a beam deflector driver is operable to oscillate the CPB at the beam sensing aperture plate so that the signal associated with the periodic attenuation of the CPB received by the beam sensing aperture is based on CPB attenuation produced by the oscillation of the CPB at the beam sensing aperture plate. In further examples, the position analyzer is situated to receive the signal associated with the periodic attenuation of the CPB by the beam sensing aperture and the oscillation of the CPB, and, based on the received signal and an oscillation of the aperture plate and/or oscillations of the CPB in one or more directions, provide the estimate of the CPB position at the aperture plate in at least one dimension. In some embodiments the CPB, the aperture plate, or both are moved in different directions so that the CPB can be characterized in the different directions.

Methods of measuring CPB position, size, or shape include producing a periodic attenuation of a CPB with a beam sensing aperture and measuring a periodic current responsive to the CPB attenuation, the periodic current associated with one or more of a transmitted, reflected, or absorbed CPB portion, or secondary emission responsive to one or more such beam portions. Based on the measured periodic current, CPB location is determined with respect to the beam sensing aperture. Typically, the periodic attenuation includes periodic attenuations in two dimensions in directions perpendicular to a CPB propagation axis and the CPB location with respect to the beam sensing aperture is determined in the two dimensions. In some alternatives, the periodic attenuation includes periodic attenuations associated with a first frequency and a second frequency that is different from the first frequency, and the CPB location with respect to the beam sensing aperture is determined in a first direction and a second direction based on the first frequency and the second frequency, respectively. In some cases, the measured periodic current is processed to obtain a component at a frequency of the periodic modulation and the CPB location with respect to the beam sensing aperture is determined based on the component.

CPB detectors comprise a conductive plate that defines an aperture that is transmissive to a CPB and least two electrically isolated conductive segments symmetrically situated about the aperture. In other examples, the at least two electrically isolated conductive segments are symmetric about an intended CPB propagation axis. An insulator layer is situated between and is secured to the conductive plate and the conductive segments. In representative examples, the conductive plate and the insulator layer define contact apertures and electrical contacts are situated in each of the contact apertures and are electrically connected to a respective conductive segment. In some embodiments, the electrical contacts are conductive pins that are retained in respective insulative housings and elastic members are situated in each of the insulative housings, each elastic member situated to urge the conductive pins into the contact apertures and against the respective conductive segments. In some cases, at least two conductors include four quarter circle segments that are electrically isolated, wherein the segments are separated by first and second radially directed and orthogonal gaps along axes that extend through a center of the aperture.

Methods comprise directing a CPB to a CPB detector having four quarter circular electrically isolated conductive segments that are distributed in a plane and azimuthally about an axis that is perpendicular to a CPB transmissive aperture, wherein each of the conductive segments has a common radius and terminates at the CPB transmissive aperture. A CPB position at the CPB detector is determined based on current differences between a first pair of the segments and a second pair of the segments, and a third pair of the segments and a fourth pair of the segments, wherein each of the first, second, third, and fourth pairs of segments is different. In some examples, the first pair of the segments is electrically isolated from the second pair of the segments by a linear gap that extends between the first pair of segments and the second pair of segments.

The foregoing and other features and advantages of the disclosed technology will become more apparent from the following detailed description, which proceeds with reference to the accompanying figures.

### BRIEF DESCRIPTION OF THE DRAWINGS

FIGS. 1A-1B illustrate representative arrays of apertures.

FIGS. 1C-1G illustrate additional representative arrangements of apertures.

FIGS. 1H-1HH illustrate recessed apertures in an insulator layer; FIG. 1HH is a sectional view of FIG. 1H.

FIG. 2A illustrates a representative method of locating an array of apertures with respect to an electron beam.

FIG. 2B illustrates a representative method of adjusting beam deflection using an aperture array.

FIGS. 2C-2G show images illustrating the method of FIG. 2A.

FIG. 3 illustrates a representative CPB apparatus with an aperture array situated for CPB alignment.

FIG. 4 illustrates a representative CPB apparatus with a beam overlap aperture situated for CPB alignment.

FIG. 5 illustrates a portion of a representative CPB apparatus showing adjustment of a beam overlap aperture and CPB deflection.

FIG. 6 illustrates a representative method of beam alignment using a beam overlap aperture.

FIGS. 7A-7C illustrate a representative quadrant CPB detector.

FIG. 8 illustrates a representative substrate for fabrication of a quadrant CPB detector.

FIG. 9 is a plan view of a representative sensor assembly that provides electrical connections to a two segment CPB detector.

FIG. 9A is a sectional view of a portion of the sensor assembly of FIG. 9.

FIG. 10 illustrates a representative embodiment of a quad beam detector.

FIG. 11 illustrates a system for determining X and Y position of a CPB using a quadrant CPB detector.

FIG. 12A illustrates a beam detector that contains eight segments.

FIG. 12B illustrates an array of quadrant beam detectors.

FIG. 13 illustrates a representative method of aligning an electron beam with an aperture using a quadrant detector as disclosed herein.

FIGS. 14A-14E illustrate use of a one-dimensional aperture array.

FIG. 15 illustrates a conductive substrate that defines detector segments.

FIG. 15A shows a central portion of the CPB detector of FIG. 15.

FIG. 16 illustrates a conductive plate that can be used in the segmented CPB detector of FIG. 15.

FIG. 17 illustrates a representative computing and control environment for any of the disclosed methods and apparatus.

FIG. 18 illustrates a representative method for additive manufacturing (AM) using any of the disclosed approaches for electron beam characterization and control.

FIG. 19 illustrates a representative AM system that includes a sensor for measuring and adjusting beam shape, size, deflections, or other beam characteristics.

FIGS. 20-21 illustrate representative AM methods.

### DETAILED DESCRIPTION

### General Considerations and Terminology

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present, or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

The examples are generally described with reference to electron beams, but any charged particle beam (CPB) can be used. While specific examples are described individually for clarity, any of these examples can be combined with any other examples. In the examples, a position of a target with respect to a CPB is measured and in some cases, the position of the target or a position of the CPB are adjusted based on the measurement. Target position is generally adjusted with a stage, a piezo-actuator, or any other positioner. CPB position is typically adjusted with an electrostatic or magnetic deflector by application of suitable voltages or currents. In most practical examples, deflectors are controlled using control voltages that are applied to deflector drive electronics which produce the intended voltages or currents provided to the CPB deflectors using one or more amplifiers or buffer circuits. As used herein, the terms “deflector drive value,” “drive values” or similar terms are used to refer to currents or voltages used to control CPB deflections. In the examples, apertures are generally illustrated as circular and are defined in a corresponding aperture plate. However, apertures can be slits, edges, polygons, ovals, or other shapes as convenient. While such apertures can be defined in dedicated aperture plates, other elements in a CPB column can be used to define these apertures as well. For convenience, CPB propagation is generally described as being along a Z-axis and apertures are situated in an XY-plane of a coordinate system.

As used herein, “image” refers to a visual display suitable for viewing by an operator, technician, or other person or to data associated with such visual displays. Images thus include data files such as jpg, tiff, bmp, or files in other formats. In some examples below, visual images are provided for purposes of explanation, but digital images are used in computations.

In the examples, mechanical stages are included to provide translations of apertures or other components along one or more axes, typically to assist in beam alignment or to establish substrate and beam positions during manufacturing operations. However, either linear or rotational stages or both can be used. Examples are described with reference to calibration and control of electron beam deflection in additive manufacturing systems that use electron beams, but the disclosed approaches can also be used in SEMs, charged-particle-beam exposure systems, and other applications. CPB current can be collected using Faraday cups or other structures and are referred to herein as CPB traps.

### Additive Manufacturing (3D Printing) Systems with Beam Sensing

Additive manufacturing systems generally manufacture parts by building up the parts layer by layer. In some cases, layer material, typically in the form of a powder, is deposited or otherwise formed at selected locations in response to an optical or charged particle beam (CPB). Typically, the optical or CPB beam is direct towards a workpiece to fuse or melt the powder at the surface of the workpiece on which a part is to be built up. The working beam (whether an optical beam or a CPB) can be scanned across the workpiece based on part design, with layer material deposited at locations to which the optical beam or CPB is scanned. In some examples, the working beam is scanned with respect to a fixed workpiece or the workpiece is scanned with respect to a fixed working beam, or both the workpiece and the working beam can be scanned. As the part layers are built up, the working beam can be refocused to accommodate height changes or the part can be translated along a working beam axis.

Particular examples of additive manufacturing systems are used for purposes of illustration. However, the disclosed methods and apparatus can be used in any type of additive manufacturing system such as a rotary table type additive manufacturing system, a linear moving stage type additive manufacturing system, and an additive manufacturing system in which a table is movable only in a single direction such as a Z direction

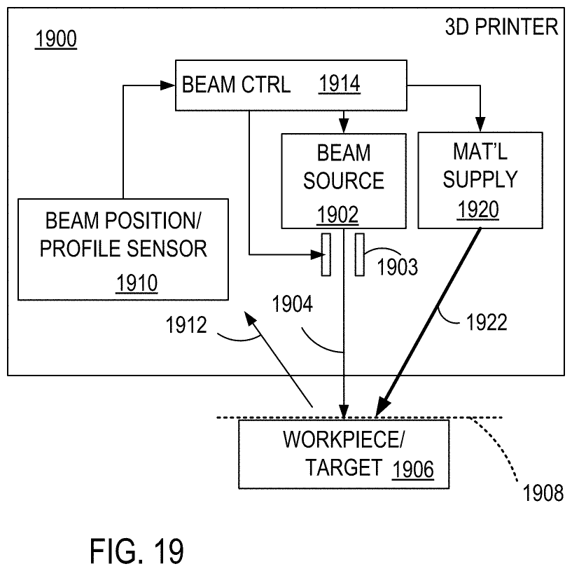

Referring to FIG. 19, a representative additive manufacturing system 1900 includes a beam source 1902 that can direct a working beam 1904 such as a CPB or an optical beam to a workpiece 1906 situated at a work surface 1908. The beam source 1902 typically includes an optical beam generator such as a laser or lamp or a charged particle beam generator such as a thermionic or field emitter that can produce an electron beam or ion beam. For either type of beam, the beam source 1902 generally includes an optical system that can comprises beam focus and beam scanners such as optical or CPB lenses, optical scanners such as electrooptic, acousto-optic, galvanometer or polygon mirror scanners, or CPB scanners such as electrostatic or magnetic scanners, but such components are not shown in FIG. 19. In FIG. 19, a beam deflector 1903 is situated to scan or otherwise direct a CPB. A sensor 1910 is situated to receive radiation 1912 responsive to the working beam such as reflected, scattered, or transmitted portions of the working beam. In addition, the sensor 1910 can be configured to receive fluorescence, cathodoluminescence, secondary emission, X-rays or other types or radiation produced in response to the working beam 1904. The sensor 1910 can include one or more apertures situated in the optical system associated with the working beam 1904 or situated at or near the work surface 1908. For example, such apertures can be situated between the beam source 1902 and the working surface 1908, at the working surface 1908, or at a side of the working surface 1908 opposite the beam source 1902. In some examples, the sensor includes one or more apertures of other components that are situated at or near the work surface 1908 with the workpiece moved away from an axis of the working beam 1904.

The sensor 1910 is coupled to a beam controller 1914 that can adjust working beam characteristics based on the received radiation. Alternatively, the sensor 1910 can include control circuitry for use in adjusting working beam characteristics. In typical examples, adjusted deflection signals are provided to the beam deflector 1903. The received radiation 1912 at the sensor 1914 is generally associated with working beam size, shape, or focus position, but can be associated with other beam characteristics. The beam controller 1914 can include one or more amplifiers, analog-to-digital convertors (ADCs), digital to analog convertors (DACs) that process electrical signals responsive to the received radiation 1912 and communicate suitable control signals (analog and/or digital) to the beam source. The beam controller 1914 can also include any of the processor based systems and components discussed below. The beam controller 1914 can be operable to control the material supply 1920, mechanical stages, beam scanning, beam power, and other manufacturing parameters but a separate local or remote control system can be provided.

A material supply 1920 is situated to direct layer material 1922 toward the work surface 1908 and the workpiece 1906. In some examples, one or both of the beam source 1902 and the workpiece 1906 are coupled to positioners such as mechanical stages that permit translations and/or rotations about one or more axes. The beam controller 1914 can be operable to control the material supply 1920, mechanical stages, beam scanning, beam power, and other manufacturing parameters but a separate local or remote control system can be provided.

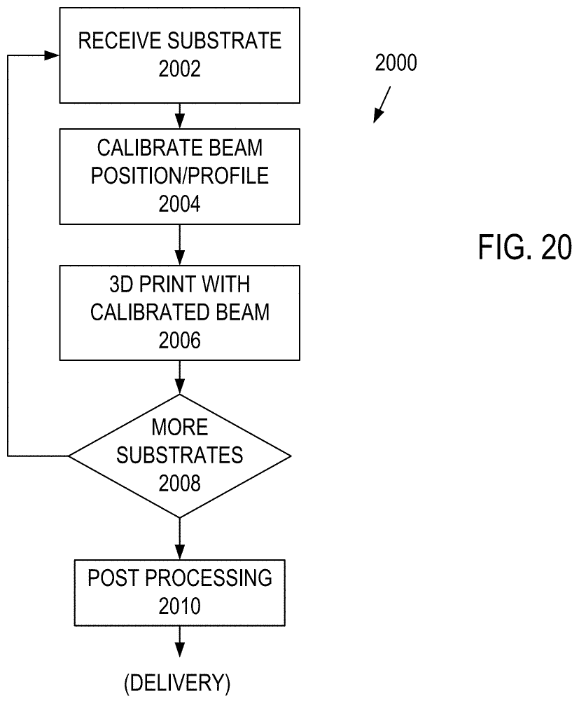

Referring to FIG. 20, a representative additive manufacturing (AM) method includes receiving a substrate at 2002 and calibrating a working beam position and/or profile using a sensor at 2004 as discussed above with reference to FIG. 19. At 2006, 3D printing is performed with the calibrated beam and at 2008 it is determined if additional substrates are to be processed. If so, a substrate is received again at 2002. As shown, calibration can be repeated at 2004 for each substrate but calibration can be omitted if unnecessary. At 2010, post processing is performed to, for example, remove excess material or remove a part from a substrate prior to part delivery. In some cases, sensors used for calibration may need to be moved into a processing beam while in other example, sensors are situated to be available without reconfiguring the AM system.

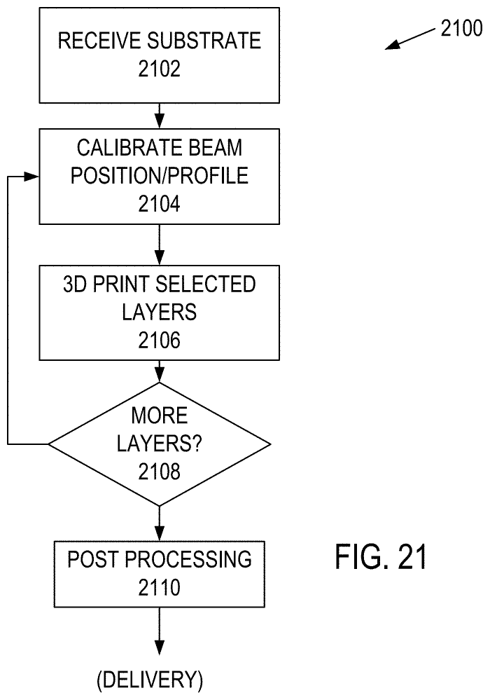

In a method 2100 shown in FIG. 21, a substrate is received at 2102 and a working beam calibrated at 2104 so that the working beam can be shaped and scanned suitably during layer formation at 2106. After a selected number of layers (any number of layers between one and all layers) are formed at 2106, if more layers are to be formed as determined at 2108, calibration can be repeated at 2106. Manufactured parts are post-processed at 2110 prior to delivery.

### Aperture Arrays

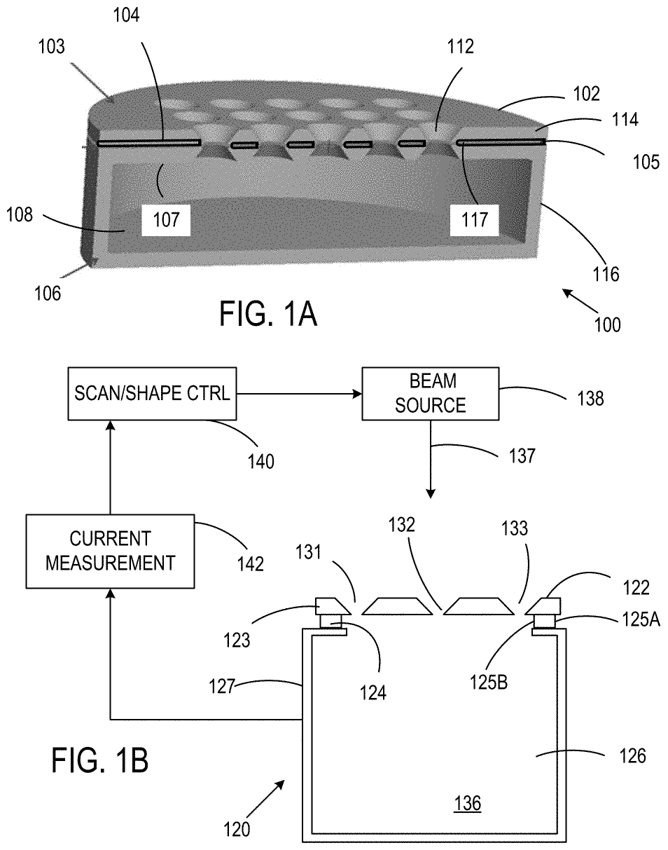

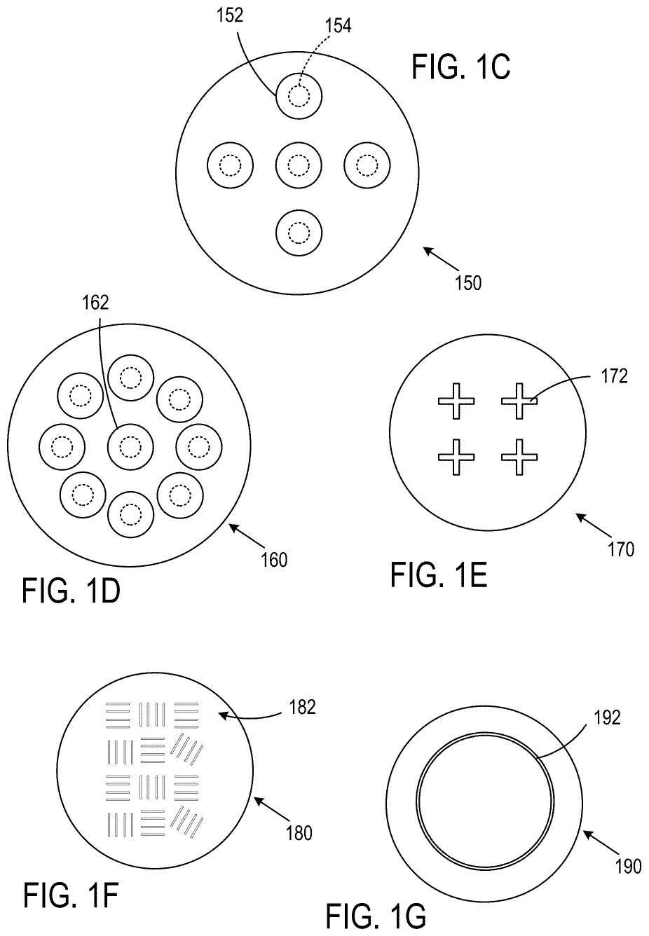

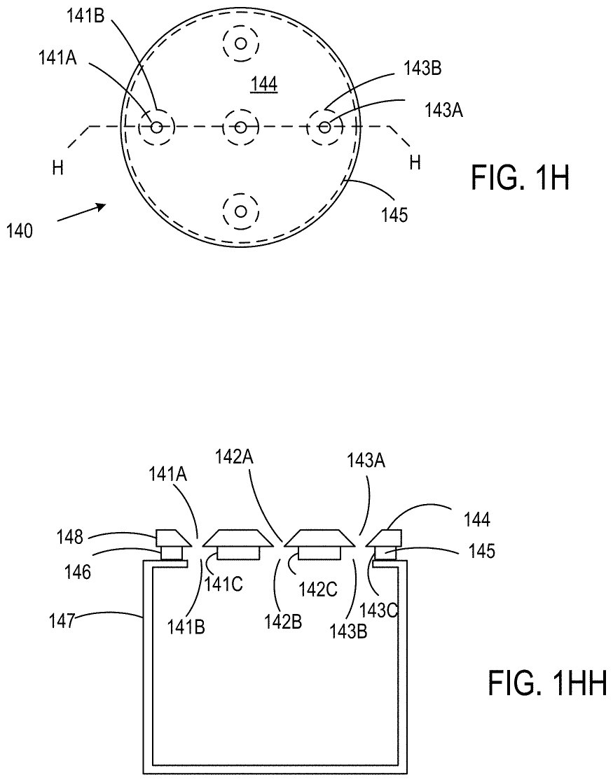

In one approach, sensors for beam calibration and characterization include aperture arrays as shown in FIG. 1A. Referring to FIG. 1A, a Faraday cup 100 includes an aperture array 102 defined in a conductive plate that is separated by an insulator layer 104 from an electron trap 106. In this example, the aperture array 102 includes a plurality of apertures such as representative aperture 112 that extend into a volume 108 defined by the electron trap 106. The apertures 110 can be circular, rectangular, or other shapes or combinations of shapes and are typically arranged in a rectangular array but other arrangements can be used such as random placements or radially or azimuthally symmetric distributions. The electron trap 106 can have a circular, rectangular or other cross section and can correspond to a portion of a rectangular or circular cylinder.

The apertures have known separations that can be periodic, fixed, random or other known arrangement and are typically spaced apart by distances greater than an electron beam diameter so that only one aperture is irradiated at a time upon exposure to the electron beam. Positions of a deflected CPB can be measured based on CPB transmission by each of the apertures into the Faraday cup 100. These CPB positions can be used to establish beam defections in AM systems such as shown in, for example, FIG. 19. In the example of FIG. 1A, a perimeter 105 of the insulator layer 104 is recessed from a perimeter 114 of the aperture array 102 and the perimeter 116 of the electron trap 106 to reduce or eliminate charging of the insulator layer 104. The apertures 110 shown in FIG. 1A taper from an exterior surface 103 to the insulator layer 104 to become narrower and taper to widen from the insulator layer 104 to an interior surface 107 of the electron trap 106. As illustrated in FIG. 1A, such tapered apertures are provided in a top 117 of the electron trap 106 but in some examples, tapered apertures are provided in the insulator layer 104 separating the conductive plate in which apertures are defined. Such tapers are not required in either the top 117 or the insulator layer 104 but can be used in one or both.

Referring to FIG. 1B, a Faraday cup 120 includes a conductive aperture plate 122 that defines tapered apertures 131-133 that extend into a volume 136 defined in an electron trap 126. An insulator layer 124 is situated at a perimeter 123 of the aperture plate 122. An exterior perimeter surface 125A of the insulator layer 124 is recessed between the aperture plate 122 and a wall 127 of the electron trap 126. In this example, the insulator layer 124 is situated only at the periphery of the aperture plate 122 and can be a circular or square ring shape, depending on the shape of the aperture plate 122. In addition, an interior perimeter surface 125B is recessed with respect to any of the tapered apertures 131-133. With recessed surfaces, charging of the insulator layer 124 can be reduced or eliminated.

The arrangement of FIG. 1B can be used as a sensor by situating the conductive aperture plate 122 at a working surface or other location of interest and scanning a beam 137 from a beam source 138 with a scan controller 140. Currents in the Faraday cup 120 are measured with an ammeter 142 or other current measurement apparatus. The measured current values are provided to the scan controller 140 to determine scan values corresponding to aperture locations and establish a calibrated scan.

Additional configurations of aperture plates are shown in FIGS. 1C-1G. In FIG. 1C, an aperture plate 150 includes tapered apertures situated along orthogonal radii. Each aperture can be the same or different. A representative aperture has an outer circular aperture 152 and extends to an inner surface as a circular aperture 154 having a smaller diameter. In the example of FIG. 1D, an aperture plate 160 includes a plurality of apertures that are situated at a common radius from a central aperture 162 and are distributed azimuthally about an axis that is perpendicular to the aperture plate 160 and through a center of the central aperture 162. An aperture plate 170 shown in FIG. 1E includes cross-shaped apertures such as representative aperture 172. In FIG. 1F, an aperture plate 180 includes repeated sequences of slits at two or more orientations such as representative sequence 182. The slits can have the same or different spacings. FIG. 1G illustrates an aperture plate 190 having a single ring-shaped aperture 192, but could include other apertures such as ring-shaped, rectangular, circular, or other shapes.

Recessed apertures in an insulator layer are illustrated in FIGS. 1H-1HH. An aperture assembly 140 includes a conductive layer 144 situated on an insulator layer 145. The insulator layer 145 is situated at a CPB trap 147. Apertures such as apertures 141A-143A are defined in the conductive layer 144 and corresponding apertures 141B-143B are defined in the insulator layer 145. The insulator layer 145 is underneath the conductive layer 144 in FIG. 1H and the apertures 141B-143C are shown as dashed lines. A perimeter surface 146 of the insulator layer is recessed with respect to a perimeter surface 148 of the conductive layer 144 and each of the apertures 141B-143B has a respective interior perimeter surface 141C-143C that is recessed with respect to a corresponding aperture 141A-141C in the conductive layer 144. The recesses are typically about 0.25, 0.5, 1, 2, 5, 10, 50, or more times greater than a thickness of either the insulator layer 145 or the conductive layer 144. Such recesses tend to reduce charging of the insulator layer 145 in response to CPB exposure.

### Beam Alignment and Apertures and Aperture Arrays

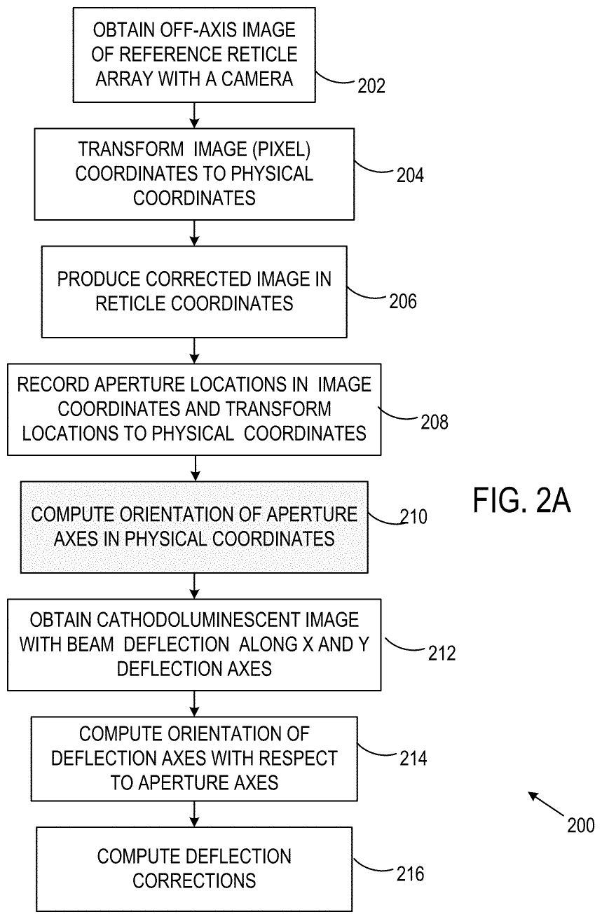

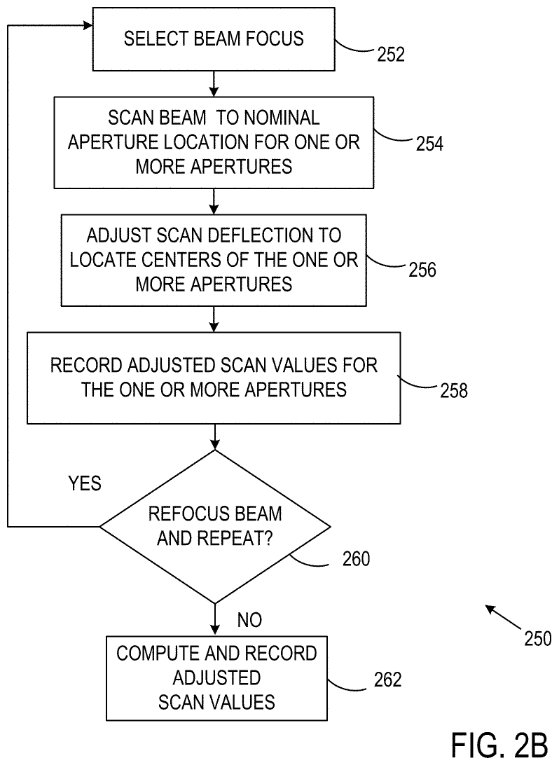

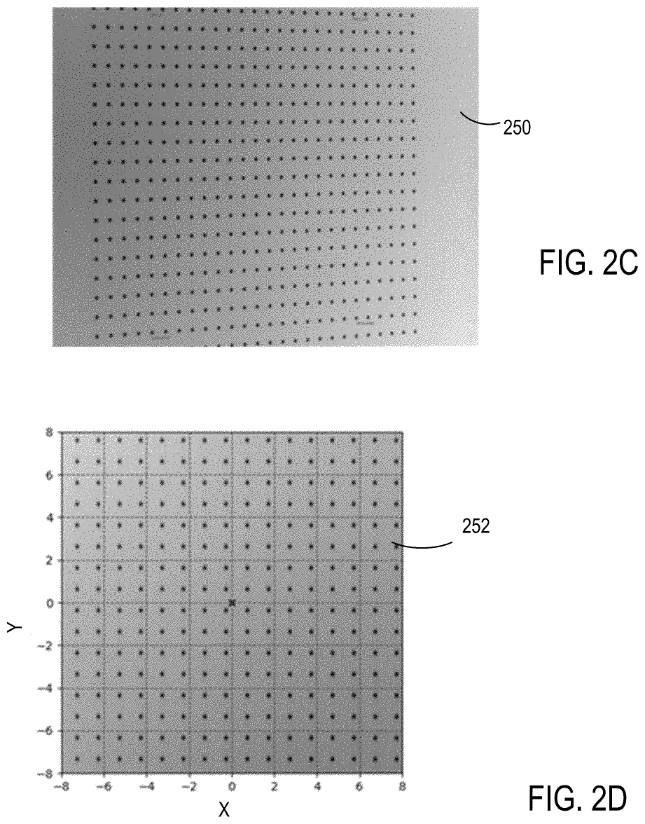

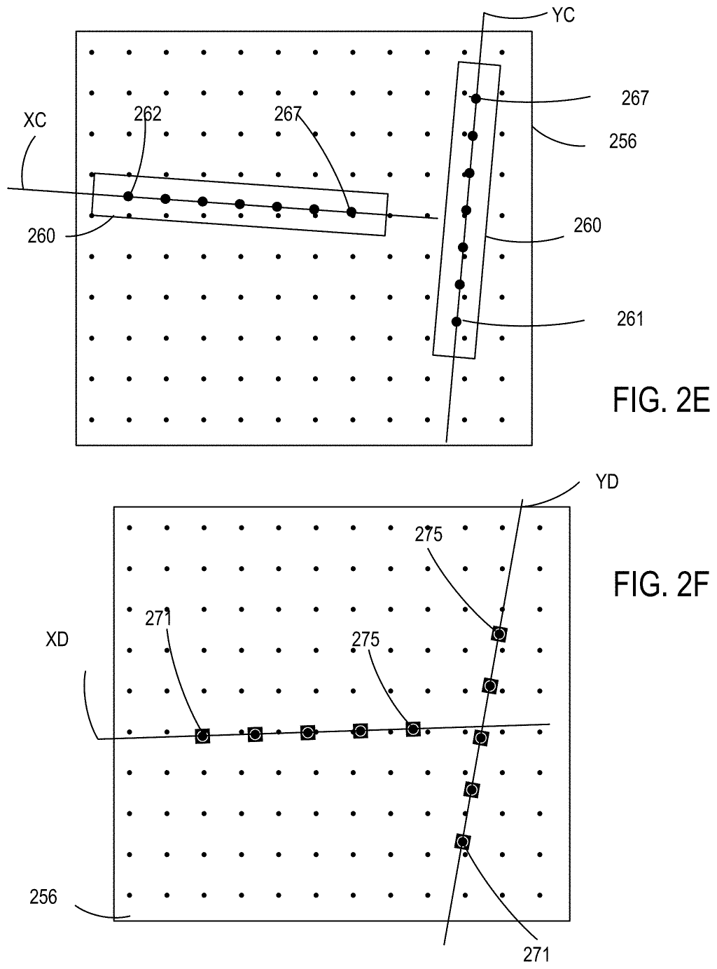

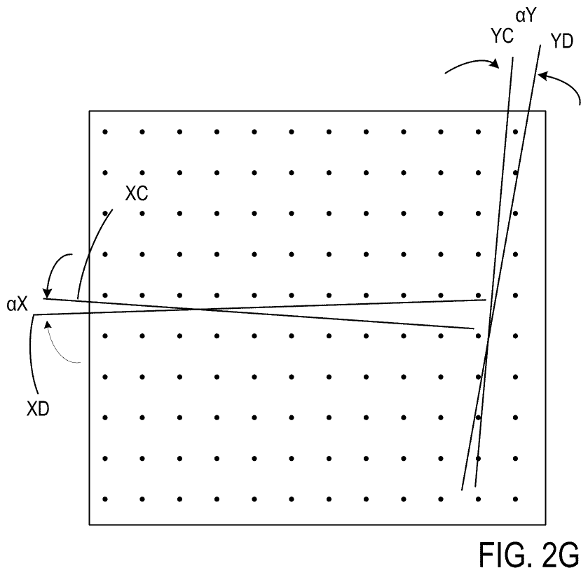

Sensors for beam calibration and characterization can also use cathodoluminescence as disclosed in FIG. 2A. In this example, a camera is used to image a reference reticle to calibrate the camera with respect to a target surface so that positions of a plurality of apertures can be established (such as in the aperture array of FIG. 1A). CPB deflections corresponding to each of the known aperture positions can then be used to establish calibrated deflections. Referring to FIG. 2A, a method 200 of calibrating beam deflections includes obtaining an image at 202 (typically an off-axis image) of a reference reticle with a camera. A typical reticle includes a regular array of markings and a representative image 250 that exhibits keystone distortion is shown in FIG. 2C. In some cases, an aperture array situated for exposure to an electron beam at 202 can be used instead of a separate reticle. At 204, image coordinates in the distorted image are transformed to physical aperture coordinates and a corrected image is produced at 206. A corrected image is not necessary but can provide confirmation of the transformation of the distorted image coordinates. A representative corrected image 252 is shown in FIG. 2D. CPB aperture locations for an aperture array are recorded in distorted image coordinates and transformed into physical coordinates at 208. FIG. 2E illustrates a one-dimensional aperture array 260 that includes apertures such as representative apertures 261, 262 oriented along a nominal X-axis and a nominal Y-axis XC, YC, respectively, shown with respect to a corrected reticle image 256. (X and Y-orientations are shown together for convenience). At 210, orientations of axes of the aperture array in physical coordinates are computed. Upon completion of the camera-based calibration procedure, a cathodoluminescent image of the deflected beam on the reticle, aperture array, or other target is obtained at 212 by exposure to an electron beam with the electron beam deflected along X and Y deflection axes XD, YD, respectively.

A target used for cathodoluminescent imaging can be unpatterned as features in the cathodoluminescent image are based on cathodoluminescence in response to the deflected electron beam. A representative corrected image (i.e., an image in physical coordinates) is shown in FIG. 2F showing representative cathodoluminescent spots 271, 275 with respect to the reference reticle image 256. As above, two orientations are shown together for convenience. A combined aperture array/cathodoluminescent image or separate images can be used. In some cases, multiple camera images may be needed to capture a full image of the aperture array and a full cathodoluminescent image. Based on the cathodoluminescent image (and the image of the aperture array whether a separate image or combined with the cathodoluminescent image), the orientation of electron beam deflection axes with respect to the aperture array axes is computed at 214, and at 216 deflection corrections can be computed. Axis orientations are illustrated in FIG. 2G, showing angles αX, αY between axes XC, XD and YC, YD, respectively. Applying these rotations aligns beam deflections with the axes of the aperture array. If desired, the aperture array can be translated or rotated with suitable actuators, and these translation and rotations can be included in the computation of deflection corrections. As noted, images need not be presented for viewing by an operator but can serve to confirm proper coordinate transforms. The images of FIGS. 2C-2G are provided to illustrate how coordinate processing in accomplished.

Referring to FIG. 2B, a representative method 250 of scanning an aperture plate with an electron beam includes selecting a beam focus at 252. At 254, the electron beam is scanned to a nominal aperture location for one more of the apertures of the aperture array. Nominal aperture locations can be obtained by, for example, the approach illustrated in FIG. 2A. At 256, scan deflections are adjusted to locate the centers of one or more apertures based on current through the apertures or currents collected by the aperture plate itself. At 258 adjusted scan values for one or more of the apertures are recorded and at 260 it is determined if the beam should be refocused and the scanning repeated. If so, the beam is refocused (generally made smaller) at 252 and the apertures are scanned again, but with nominal locations updated based on the previous electron beam scan. If additional focus settings are not to be used, at 262, the adjusted scan values are recorded for use in subsequent scanning. It should be noted that the method in 250 can be performed either with stepwise scanning, in which the beam is sequentially moved to the vicinity of each aperture and measurements are made, or with continuous raster or boustrophedonic scanning, in which the beam is continuously swept across an aperture array and signals are obtained by “unwinding” or decoding time-dependent signals.

### Electron Beam System with Aperture Array Alignment

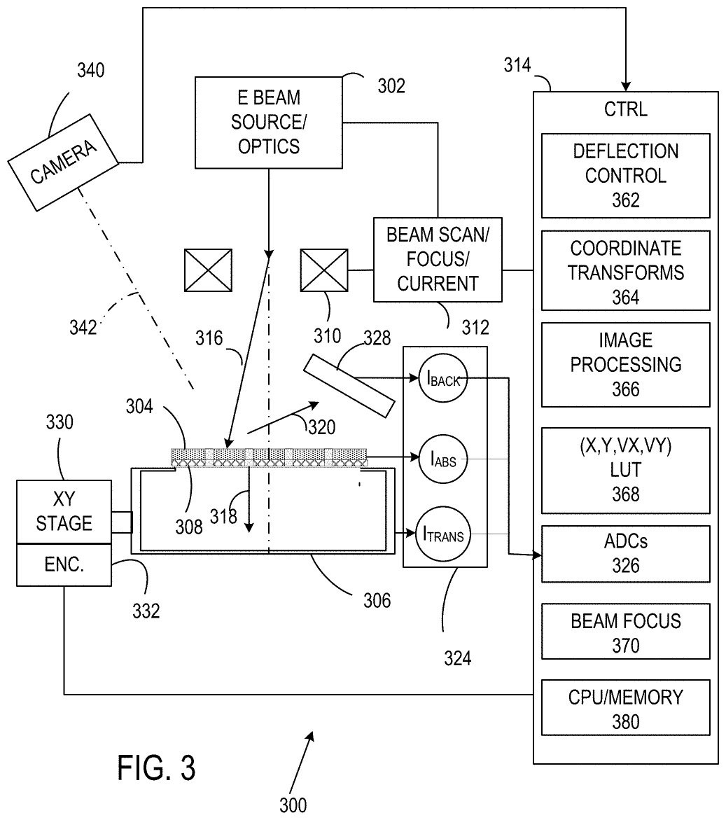

FIG. 3 illustrates one example of a CPB apparatus with a Faraday cup situated for measuring CPB position. Referring to FIG. 3, a representative electron beam system 300 includes an electron beam source/electron optics 302 that directs an electron beam to an aperture array 304 such as shown above that is separated from Faraday cup 306 by an insulator layer 308. A beam deflector 310 is coupled to deflection/focus/beam current control circuitry 312 to provide beam deflections in response to control signals or processor-executable instructions provided by a system controller 314 and produce a deflected beam 316. Currents associated with a current 318 transmitted by the aperture array, absorbed by the aperture array 304, or a current 320 associated with beam backscattering or secondary electrons are directed to a current detector 324, illustrated as current meters receiving currents I_{TRANS}, I_{ABS}, I_{BACK}, respectively. In one embodiment, three current detectors 324 can be provided for receiving currents I_{TRANS}, I_{ABS}, I_{BACK}, respectively. Currents can be measured using resistors as current-to-voltage convertors and measuring the associated voltages. Measured values are coupled to the controller 314 digitally or using an analog-to digital convertor (ADC) 326 that can be included in the controller 314 or be provided separately. Back scattered electrons or secondary emission can be received at a charge detector 328.

The aperture array 304 can be secured to an XY stage 330 which is coupled to an encoder 332 that can also be coupled to the controller 314 to adjust positioning of the aperture array 304. A camera 340 is situated on an axis 342 that is tilted with respect to a perpendicular to the aperture array 304. The camera 340 can provide cathodoluminescence images to the controller 314 for use in array alignment but is not necessary

The controller 314 can include a beam deflection controller 362, memory portions 364, 366, 368, 370 that store processor-executable instructions for coordinate transforms, image processing, deflection look up table values VX,VY associated with a particular location (X,Y), and beam focus control, respectively. The controller 314 also includes one or more processors and additional memory as shown at 380.

In the example of FIG. 3, a sensor for beam calibration and characterization can include one or more of the current detectors, the aperture array 304, a charge detector 328, and the camera 340 for characterization using an aperture array, transmitted, absorbed, or backscattered charge or current and/or cathodoluminescence.

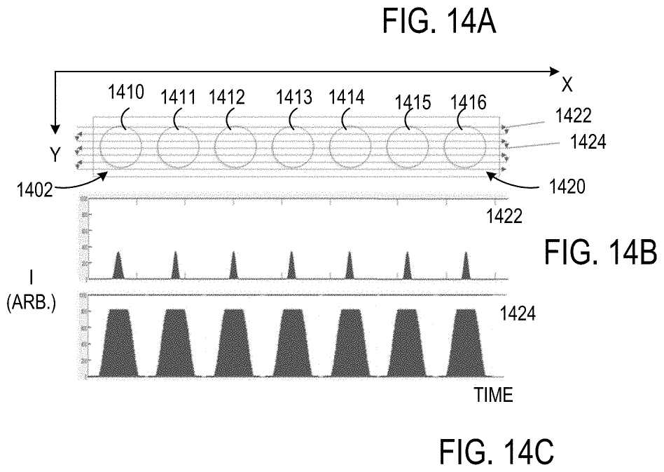

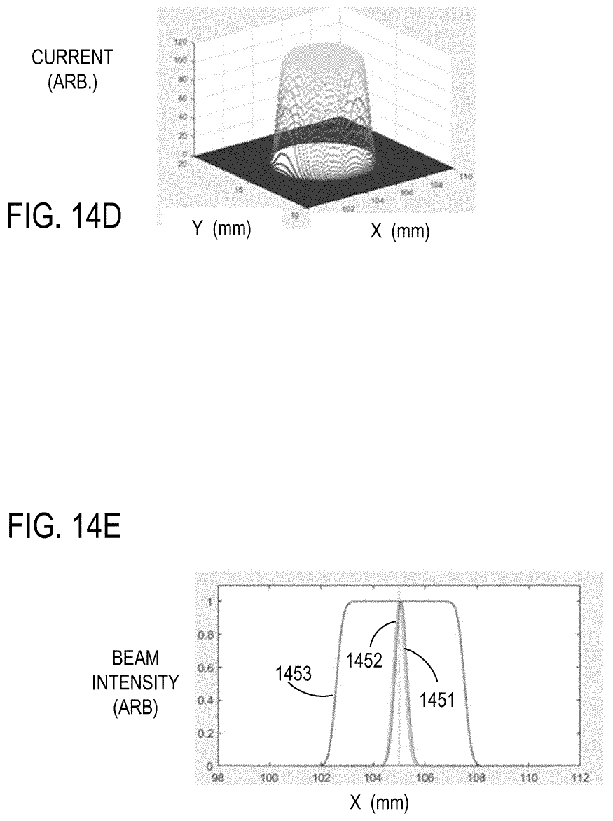

One Dimensional Calibration Beam position, shape, and size can be measured and compensated using, for example, X- and Y-stages that can operate continuously or in steps (step-wise) while a collected current is measured at one or more apertures. In one example shown in FIG. 14A, a one-dimensional array 1402 of apertures/Faraday cups 1410-1416 is used that can be installed to extend along an X-axis. An electron beam is scanned in a raster pattern 1420 across the Faraday cups 1410-1416 and current collected with a common collector so that current can be measured but without identification of an associated Faraday cup. Current as function of time for representative raster lines 1422, 1424 is graphed in FIGS. 14B-14C. In these graphs, time corresponds to X-coordinate and the current peaks of FIG. 14B correspond to signals produced by the Faraday cups 1410-1416. In FIG. 14C, the raster line 1424 scans from right to left so that the current peaks correspond to Faraday cups 1416-1410. FIG. 14D is a two-dimensional plot of current for selected Faraday cup and FIG. 14E shows electron beam intensity 1451 in the X-direction obtained by deconvolving the distribution of FIG. 14D (shown as curve 1453) using Faraday cup diameter. Curve 1452 shows electron beam intensity as measured directly. The array 1402 can be rotated to determine beam characteristics along a Y-axis.

### Sensor with Variable Overlap Sensing Apertures

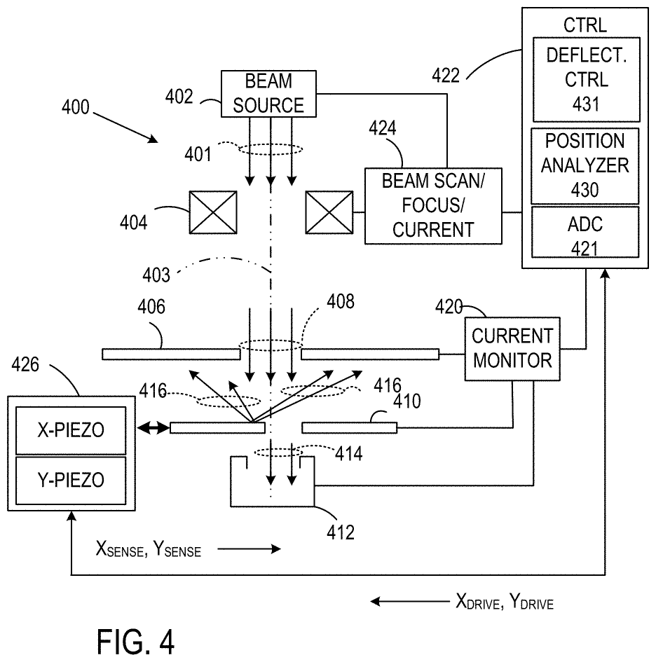

Referring to FIG. 4, a representative electron beam system 400 includes a beam source 402 that directs an electron beam 401 along an axis 403 through a deflector 404 and a back-scattered charge detector 406 having an aperture 408. The electron beam is then directed towards an overlap sensing aperture 410 and into an electron trap 412. A transmitted beam portion 414 is collected by the electron trap 412 and a back-scattered portion or secondary emission 416 are directed to the detector 406. As illustrated, the overlap sensing aperture 410 absorbs a portion of the electron beam 401. One or more of these currents are directed to a current monitor 420 which is in turn coupled to a control system 422. The current monitor 420 can provide analog current signals to an ADC 421 or current signals can be provided as digital values directly to the control system 422. In one embodiment, plurality of current monitors 420 can be provided for receiving each of currents from different devices. The beam deflector 404 is coupled to a scan controller/driver 424 that is also coupled to the control system 422.

The overlap sensing aperture 410 is coupled to piezo actuator system 426 that is operable to repetitively, periodically, randomly, or otherwise arbitrarily translate the overlap sensing aperture 410 with respect to the axis 403 to variably attenuate the electron beam 401. The piezo system 426 is coupled to the control system 422 to receive drive signals X_{DRIVE}, Y_{DRIVE} and report sensed location X_{SENSE}, Y_{SENSE}. Oscillation or other translations of the overlap sensing aperture 410 produce modulation of some more or all of the currents associated with beam transmission, absorption, or scattering and this modulation is dependent on a relative position of the overlap sensing aperture 410 with respect to the electron beam 401. Some or all of these modulations are used by a position analyzer 430 to establish beam position with respect to the overlap sensing aperture 410 and provide adjusted deflection values to a deflection control system 431.

### Overlap Sensing System

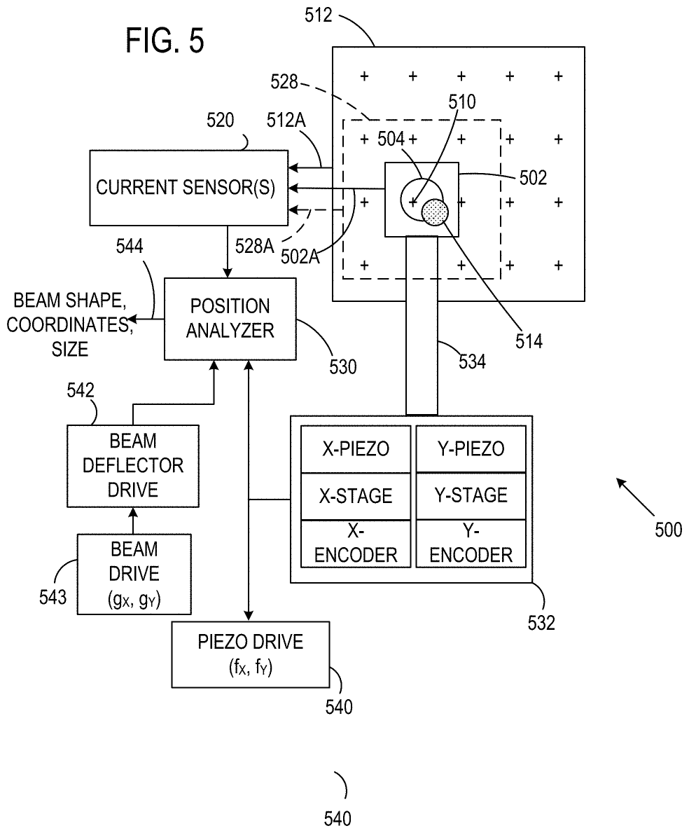

Referring to FIG. 5, an overlap sensing system 500 includes an overlap aperture plate 502 that defines an beam sensing aperture 504. The overlap aperture plate 502 is shown as placed with respect to a particular target location 510 with a plurality of additional target locations shown on a target surface 512. An electron beam is directed to the overlap aperture plate 502 and is shown as a beam spot 514. Transmitted, absorbed, or scattered beam portions produce currents that can be directed to one or more current sensors 520. An electrode 528 for capturing backscatter is shown as a dashed outline. The current sensors 520 provide current signals to a position analyzer 530 that can output deflection calibrations or beam coordinates. As shown in FIG. 5, currents from some or all of the overlap aperture plate 502, the target surface 512, and the electrode 528 are directed along conductors 502A, 512A, 528A, respectively, to the current sensors 520. In one embodiment, plurality of current sensors 520 can be provided for sensing currents from different devices.

In a typical example, an actuator system 532 is coupled to the overlap aperture plate 502 with a rigid member 534. The actuator system 532 includes an X-piezo, Y-piezo, X-stage, Y-stage and respective X and Y encoders. A piezo drive 540 can provide drive signals at different frequencies f_{X}, f_{Y} to the X- and Y-piezos, respectively. Based on the drive signals and beam deflection signals from a beam deflector drive 542, the position analyzer determines beam position, shape, and/or size and can provide beam coordinates at an output 544. The beam coordinates can be used to map beam deflections into physical beam positions to permit accurate beam positioning and estimation of beam shape and size. Currents can also be decoded to determine beam size and shape.

Instead of or in addition to piezo or substrate stage driven movement of an aperture, a beam deflection can be operable to oscillate a position of a CPB with respect to the aperture. For example, the system 500 can include a beam drive source 543 that can provide variable (typically oscillatory) signals g_{X}, g_{Y} to the beam deflector drive 542. These signals can deflect the electron beam in the X- and Y-directions, and the beam sensing aperture 504 can be stationary (or can oscillate or otherwise move as well). In some cases, the signals are at different frequencies which can aid estimation of one or more of beam position, shape, and size in the different directions. Drive signals for the beam deflector drive 542 and the piezos are shown as separate components in FIG. 5, but such drive signals can be provided by the position analyzer 530, the beam deflector drive 542, or the actuators system 542 or by some other portion of the system 500 such as a system controller (not shown in FIG. 5).

### Overlap Sensing Method

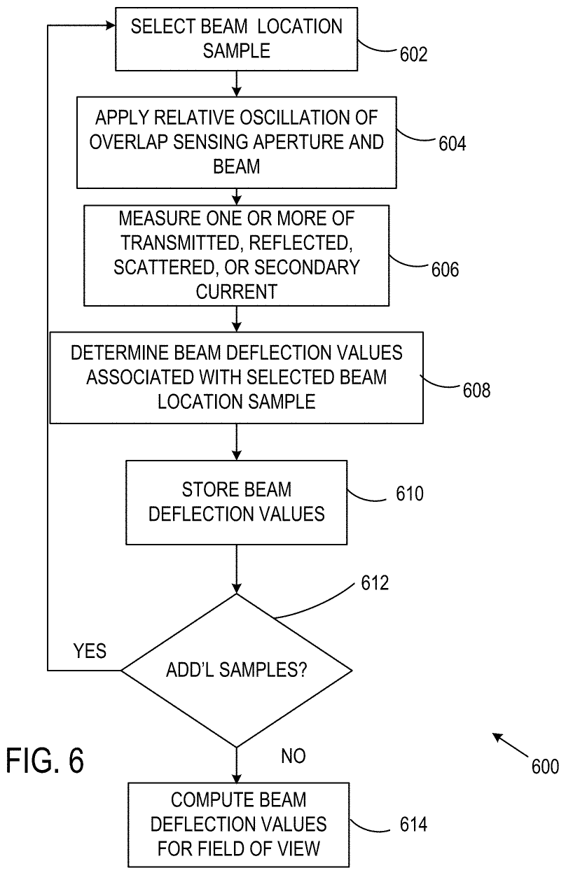

Referring to FIG. 6, a method 600 for computing beam deflection values for a field of view using the systems of FIGS. 4-5 or other systems includes selecting a sample beam location at 602. At 604, a relative oscillation of an overlap sensing aperture with respect to an electron beam is applied and at 606, one or more of transmitted, reflected, scattered, or secondary current in response to a CPB are measured. Deflection values associated with the selected sample beam location are determined based on modulations in the measured current or currents associated with the relative oscillation at 608. By placing the overlap sensing aperture precisely at the sample beam location with the X-stage and Y-stage, offsets in beam position can be assessed and corrected using the current modulations. At 610, the beam deflection values for the sample location are stored. At 612, it is determined if additional sample locations are to be evaluated and if so, processing returns to 602 for selection of another beam sample location. If no additional sample locations are to be used, beam deflections for a field of view are computed at 614. Although periodic oscillation of an overlap sensing aperture can be convenient, other translations or tilts can be used.

### Segmented Beam Sensors

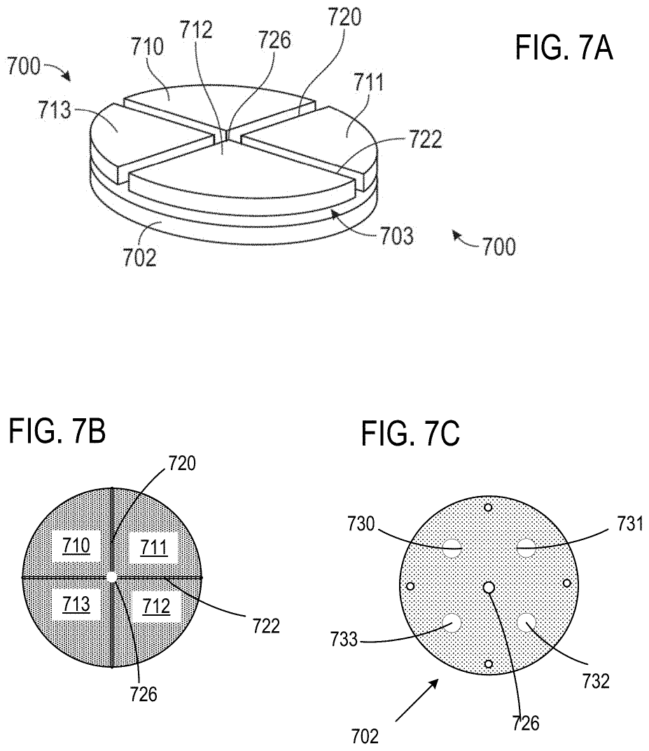

A representative segmented beam sensor 700 for beam alignment is illustrated in FIGS. 7A-7C. Referring to FIGS. 7A-7B, conductive segments 710-713 are separated by gaps 720, 722 and are secured to insulator layer segments situated in a gap 703 but not extending into the gaps 720, 723. The insulator layer segments are secured to a conductive base 702 so that the conductive segments 710-713 are electrically isolated. The conductive segments 710-713 terminate above an aperture 726 that is centrally situated on the sensor 700. FIG. 7C shows the conductive base 702 in which through holes 730-733 are defined that provide access to the conductive segments 710-713 for electrical connections. The insulator layer segments also include corresponding through holes. In some cases, the insulator layer segments are formed of an electrically insulating, thermally conducting adhesive. The example of FIGS. 7A-7C is a quad segment detector in which the segments are quarter circles separated by gaps and terminating at the aperture 726. The segments 710-713 of FIGS. 7A-7B can be subjected to high beam powers and can be made of conductors such as tungsten that are suitable for high temperatures produced in response to high power beams. In addition, it is preferable that parts exposed to a CPB be readily replaceable as exposure to high beam powers can cause damage. In the configuration of FIGS. 7A-7B, the segments 710-713 can be straightforward to replace. Alternatively, the entire assembly can be replaced as it can be inexpensive to produce. Such segmented apertures can also be used to define beam sensing apertures such as the beam sensing aperture 504.

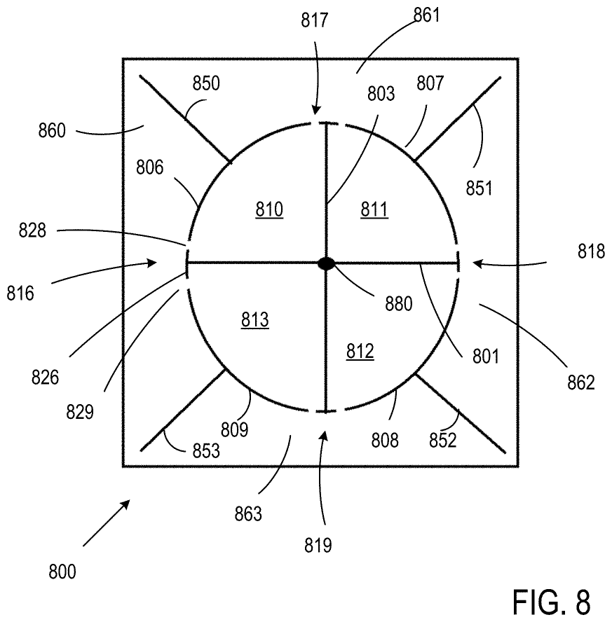

FIG. 8 illustrates a representative conductive substrate 800 processed by laser machining, electrical discharge machining, or otherwise to produce quarter circle (quad) segments 810-813 that are separated by gaps 801, 803, forming a quad. This illustrates one example of a method of constructing the quad cell for a beam sensor such as shown in FIG. 7 without additional alignment steps in construction. The substrate is cut through to define a circle at cut lines 806-809 but leaving regions 816-819 that include cut lines and gaps. For example, the region 816 includes a circular cut segment 826 that is separated from cut lines 806, 809 by uncut areas 828, 829, respectively. Similar arrangements are provided at regions 817-819. Additional cuts 850-853 extend from the circular cuts 806-809 toward respective corners of the conductive substrate 800. A central aperture 880 is also cut. With such cuts, the conductive substrate 800 (such as tungsten) can be cut along all four corners and then bent along uncut areas of the regions 816-819 to remove the outer areas 860-863 to separate and leave only the quad segments 810-813. It is especially convenient to secure the substrate 800 to a conductive layer with an electrically insulating adhesive, then cut and bend the substrate 800 as previously described to leave only the isolated quad segments 810-813. With this approach, no additional alignment of the quad segments 810-813 is needed.

### Two Cell Connection Assembly

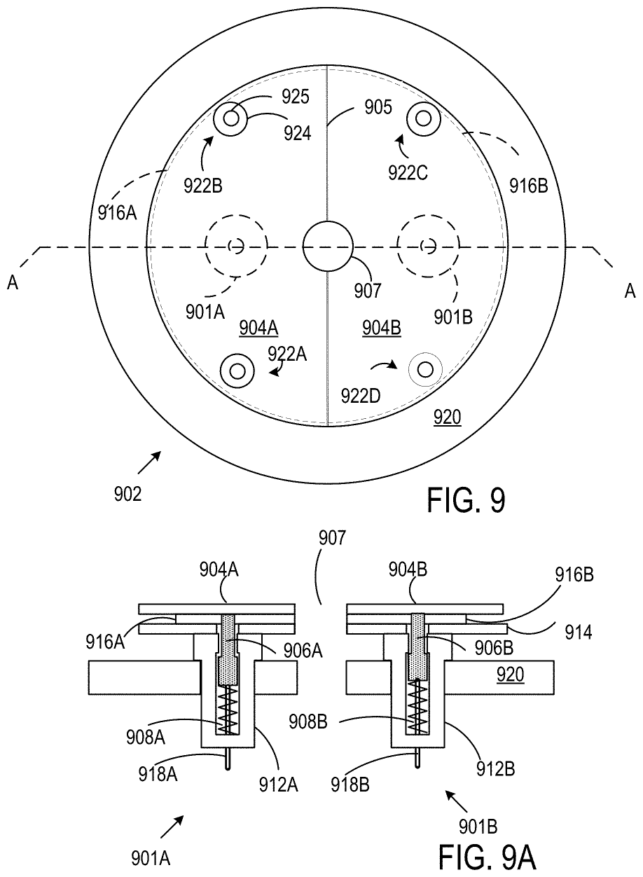

FIGS. 9-9A illustrate a representative sensor assembly for a two-segment sensor 902. As shown in the plan view of FIG. 9, the two-segment sensor 902 includes semicircular conductive segments 904A, 904B that are electrically isolated by a gap 905. The semicircular conductive segments 904A, 904B terminate at a CPB transmissive aperture 907, but such an aperture is not needed if the sensor assembly 902 is to be removed after beam shape, size, or position have been measured. As shown in the sectional view of FIG. 9A, the two-segment sensor 902 includes insulative adhesive layer segments 916A, 916B that secure the conductive segments 904A, 904B to a conductive base 914. First and second connection assemblies 901A, 901B include springs 908A, 908B situated to urge conductive pins 906A, 906B that are retained in insulative housings 912A, 912B to electrically contact respective conductive segments 904A, 904B. In this way, electrical connections to the conductive segments 904A, 904B can be made without wired connections, permitting simple replacement of the conductive segments 904A, 904B. The conductive pins 906A, 906B are electrically coupled to wires 918A, 918B that can direct absorbed beam current to a measurement device such as a current meter. The connection assemblies 901A, 901B are retained in a conductive base 920 that is secured with respect to a CPB column. Locations of the connection assemblies 901A, 901B are shown in dashed lines in FIG. 9 as they are located underneath the conductive segments 904A, 904B. In addition, apertures 922A-922D can be used for fasteners such as screws that can be used to secure the two-segment sensor 902 to the conductive base 920. These apertures generally include a clearance aperture such as representative aperture 924 so that electrically conductive fasteners passing through inner apertures such as representative inner aperture 925 do not electrically contact the sensor segments 904A, 904B.

### Quad Cell Connection Assembly

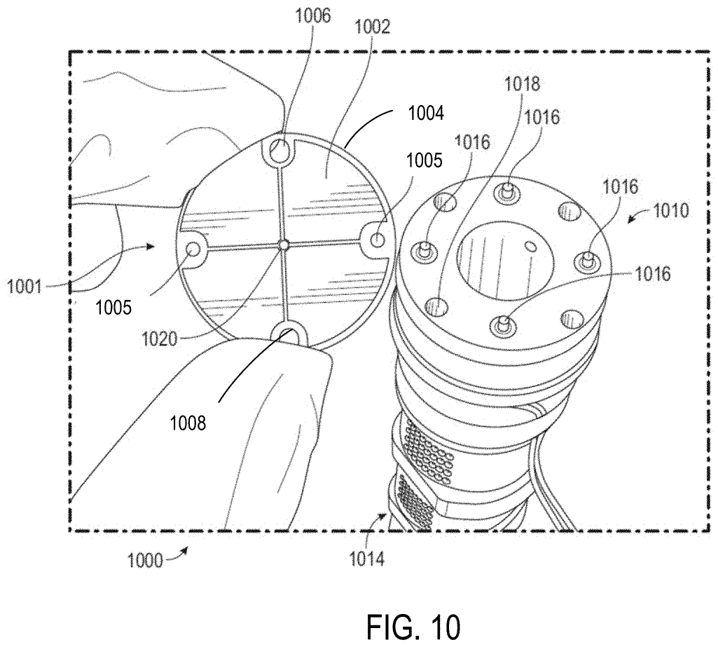

FIG. 10 further illustrates a quad cell, electrical connection to the quad cell, and placement of the quad cell for use with respect to the electron beam column. A quad cell assembly 1001 includes a quad cell (i.e., four conductive segments) 1002 that is secured via insulating adhesive layer segments (not shown) to a conductive base 1004 that has a through hole and slot such as mounting features 1006, 1008 (such slots) that can be used to secure the quad cell 1002 to a connector assembly. The conductive base 1004 also includes holes 1005. The mounting features 1006, 1008 are tight fitting to eliminate the need for positioning adjustment. Connector assembly 1010 includes conductive pins 1016 for contacting respective quad cell segments through corresponding apertures in the insulating adhesive layer and the conductive base 1004 and tapped holes such as tapped hole 1018 are provided to secure the quad cell assembly 1001 to the connector assembly 1010 with screws. The conductive base 1004 and the insulator layer contain holes that permit the conductive pins to contact the quad cell segments, but these are not shown in FIG. 10. The quad cell 1002 has a central aperture 1020 that is transmissive to an electron beam. The central aperture 1020 extends through the insulating adhesive layer segments and the conductive base.

### Beam Measurements with Segmented Detectors

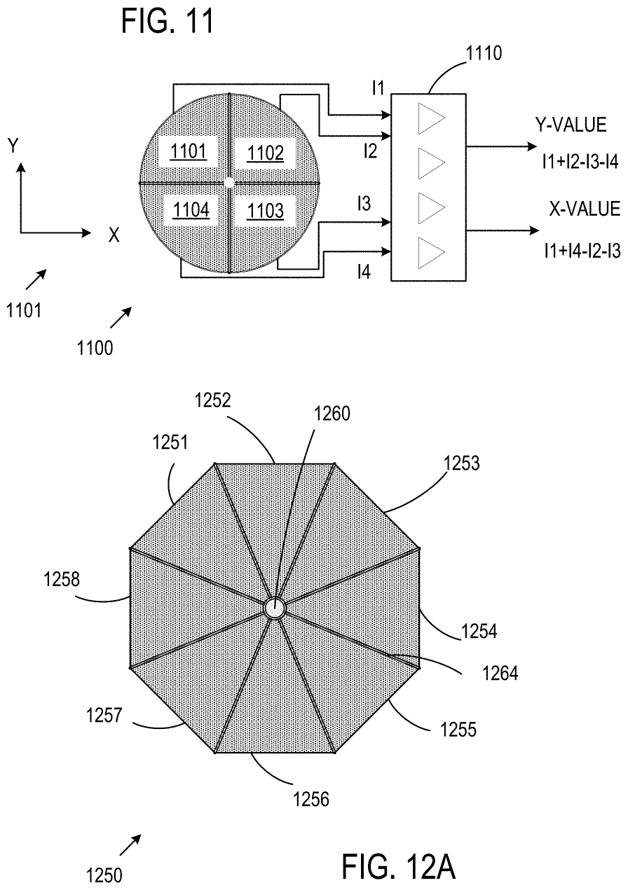

Referring to FIG. 11, a sensor system 1100 includes quad segments 1101-1104 that are coupled to a current measurement system 1110 that includes buffer amplifiers and other conditioning circuitry as well as sum and difference amplifiers or sum or other hardware or processor-executable instructions that can provide signal output based on current sums and differences of quad segment currents. As shown, segments 1101-1104 are associated with currents I₁, I₂, I₃, I₄, respectively. In a coordinate system 1001, an X-value of beam position and a Y-value of beam position are obtained as shown. Other combinations of currents I1-I4 can be used.

### Other Segmented Detectors

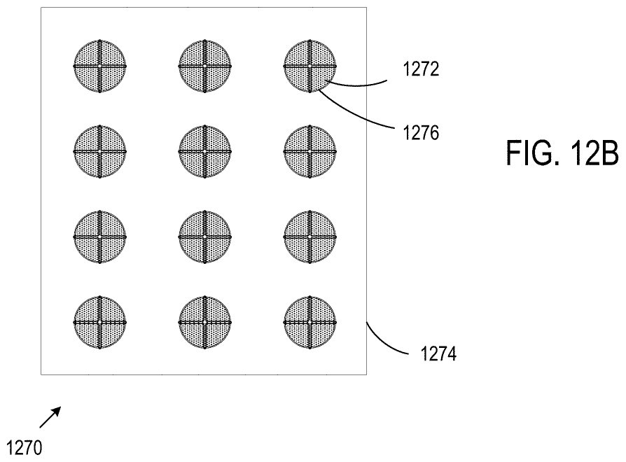

Referring to FIG. 12A, a segmented detector 1250 includes conductive segments 1251-1258 that correspond to portions on an octagon. An outer perimeter of the segmented detector 1200 is shown as octagonal but can be circular or other shapes. The conductive segments 1251-1258 terminate at an aperture 1260 and are electrically separated by gaps such as representative gap 1264. The segments 1251-1258 are typically separated by a segmented insulator layer from a conductive base but these are not shown in FIG. 12A. In this sensor, the overlap between the beam and the aperture will be modulated. The modulation can be driven by piezoelectric actuators driving the motion of the aperture in a direction perpendicular to the beam propagation direction or by beam deflection oscillations with respect to one or more of the conductive segments 1251-1258 and the aperture 1260.

FIG. 12B illustrates a sensor 1270 that includes an array of quad sensors or other multi-segment sensors such as representative sensor 1272 formed in a conductive plate 1274. Each of the quad sensors include four electrically isolated segments and a central aperture. In addition, each quad sensor is electrically isolated from the conductive plate 1274 by a gap such as representative gap 1276 that extends about the perimeter of the sensor 1272.

### Beam Location with Segmented Detectors

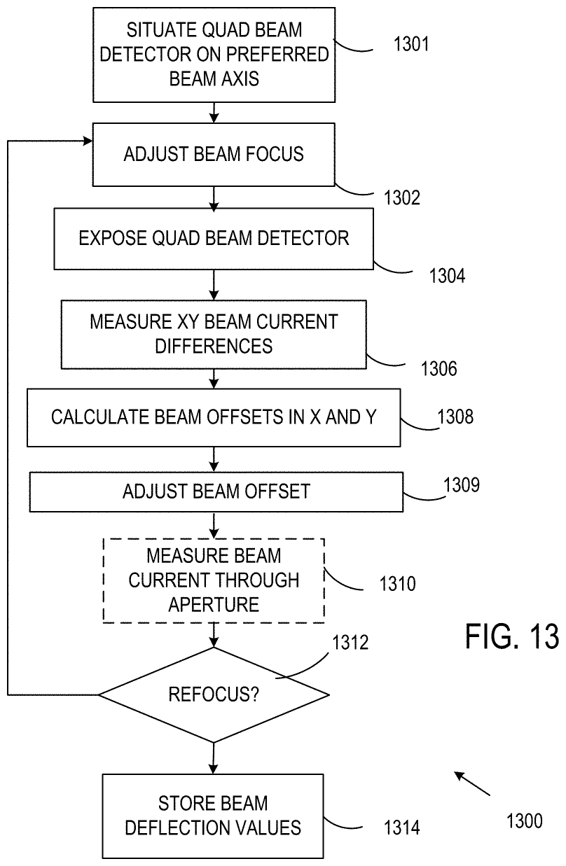

Referring to FIG. 13, a representative method 1300 of using a segmented detector such as a quad beam detector includes situating the quad beam detector on a preferred axis of an electron beam system at 1301 and adjusting an electron beam focus at 1302. In some examples, a defocused beam is used initially to avoid damage to the quad segments due to high beam powers. In addition, with more beam current incident to the quad cell segments (rather than the aperture) during the alignment process, current sums and differences can have higher signal to noise ratios and can thus be more useful during alignment. The quad beam detector is then exposed to the electron beam at 1304 and currents at each segment are measured at 1306. At 1308, beam offsets in X and Y directions are calculated based on the measured currents and at 1309, one or both of beam deflection and quad beam detector location are varied so that the electron beam is more centrally located at the quad beam detector. Beam deflection values associated with the beam location can be stored as well. At 1310, beam current transmitted by the quad beam detector aperture can be measured. At 1312, it can be determined that the electron beam is to be refocused, typically to make the beam cross section smaller so that more current is transmitted by the quad beam detector aperture and permit higher resolution beam location. However, refocus is generally unnecessary. If a refocus is selected, the method 1300 returns to 1302. Otherwise, beam deflection values associated with the quad beam detector location are stored for use in controlling beam deflection during use of the electron beam system.

In some approaches, a focus lens current is set to defocus and beam deflectors set to deflect a beam to a nominal center. The beam is turned on, xy-offsets are measured, and beam deflectors are adjusted and beam current measured until offsets are zero or approach zero. Focus is then tightened and offsets are verified as zero. The beam is then fully focused and the focused beam is generally transmitted through the aperture, except for some generally small stray portions.

### Representative Segmented Detector

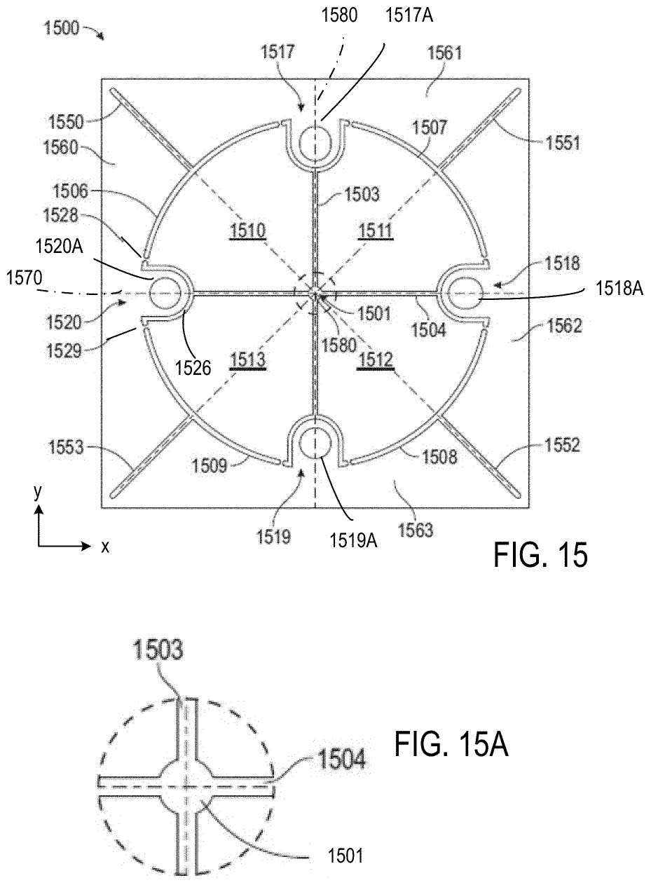

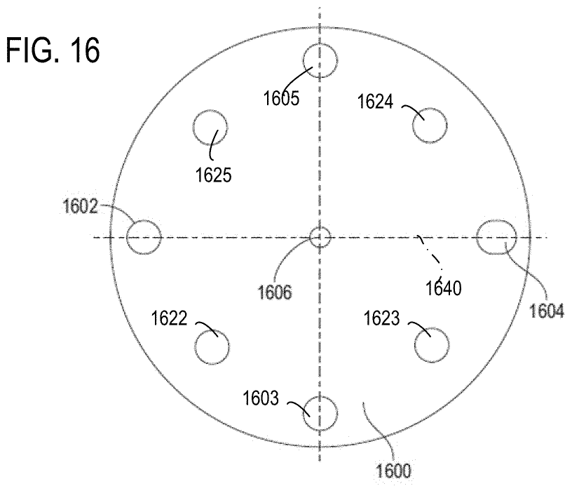

FIGS. 15-15A illustrate a representative conductive substrate 1500 processed by laser machining, electrical discharge machining, or otherwise that can be used to produce quarter circle (quad) segments 1510-1513 that are separated by gaps 1503, 1504. The substrate 1500 is cut through to define a circle at cut lines 1506-1509 but leaving regions 1517-1520 that include cut lines and gaps. For example, the region 1520 includes a circular arc-shaped cut segment 1526 that is separated from cut lines 1506, 1509 by uncut areas 1528, 1529. Similar arrangements are provided at regions 1517-1519. Additional cuts 1550-1553 extend from the circular cuts 1506-1509 toward respective corners of the conductive substrate 1500. A central aperture 1501 is also cut. With such cuts, the conductive substrate 1500 (such as tungsten) can be bent along the cut lines to remove the outer areas 1560-1563 to separate and leave only the quad segments 1510-1513. It is especially convenient to cut the conductive substrate 1500 as shown, secure the substrate 1500 to a conductive layer with an electrically insulating adhesive, and then bend the conductive substrate 1500 along the cut lines to leave only the quad segments 1510-1513. With this approach, no additional alignment of the quad segment 1510-1513 is needed.

As shown in FIG. 15, each of the regions 1517-1520 of the conductive substrate 1500 is associated with a respective hole 1517A-1520A that can be used for alignment in securing the conductive substrate 1500 to a conductive back plate. For example, the holes 1518A, 1520A can be placed to engage respective pins in an assembly fixture and align the conductive substrate on the assembly fixture. The hole 1520A is round and the hole 1518A is elongated along an axis 1570. Engagement of the hole 1520A with a pin of the assembly fixture determines x,y positions of the quad segments 1510-1513 while the elongated hole 1518A controls in-plane rotation. The holes 1517A, 1519A can be used to align the conductive substrate 1500 and a back plate. The hole 1519A is round and the hole 1517A is elongated along an axis 1580. Engagement of the hole 1520A with a pin placed in the back plate determines x,y positions of the quad segments 1510-1513 with respect to the back plate while the elongated hole 1517A controls in-plane rotation of the conductive substrate with respect to the back plate. After the conductive substrate 1500 is aligned with and secured to a conductive back plate, the outer areas 1560-1563 defining the holes 1517A-1520A are removed.

FIG. 16 illustrates a conductive back plate 1600 to be used with segments such as those shown in FIG. 15. The conductive back plate 1600 includes a central aperture 1606 that is transmissive to CPBs and perimeter holes 1602-1605 to be used in assembly and mounting. The holes 1602, 1603, 1605 are circular and the hole 1604 opposite the hole 1602 is elongated along the axis 1640. The circular hole 1602 and the elongated hole 1604 can be used to align the conductive back plate 1600 and a quad cell during assembly and then used for mounting when assembly is complete. The circular hole 1602 can be used with a pin that engages the circular hole 1602 to establish x,y coordinates of a quad cell assembly while the elongated hole 1604 can be used to set rotation of the quad cell assembly. Contact holes 1622-1625 permit electrical connections to quad segments to pass through the conductive back plate 1600 without electrical contact to the conductive back plate 1600.

A conductive back plate and a conductive substrate that defines quad or other segments such as shown in FIGS. 15-16 are typically secured with a non-conductive adhesive. To avoid contact of the conductive back plate and the conductive substrate, a perimeter spacer can be used between the conductive back plate and the conductive substrate and removed after they are secured to each other or left in place. Alternatively, an insulative spacer material can be applied to one of the parts or mixed into an adhesive. For example, glass or plastic beads or rods, can be mixed into the adhesive. An insulative spacer material can also be deposited by printing or other technique onto one or both of the back plate and the conductive substrate. Alternatively, the conductive back plate 1600 can be aligned with a fixture that contains pins corresponding to holes 1602, 1604. In addition, the fixture can include additional pins situated to extend through the contact holes 1622-1625 and typically 25 μm to 200 μm longer than a thickness of the conductive back plate 1600. The conductive back plate 1600 is situated on the fixture and an insulative vacuum epoxy is applied at the pins that extend through the contact holes 1622-1625. A conductive substrate for detector segments (e.g., the substrate 1500) is aligned with the pins that extend through the holes 1602, 1604 and contacts the uncured vacuum epoxy. The epoxy is applied to the conductive back plate 1600 at each of the contact holes 1622-1625 in quantities sufficient to secure the parts, but not extend to a perimeter or to approach the central aperture 1606. Insulative materials at edges can be exposed to an electron beam and acquire undesirable charge. The pins extending through the contact holes 1622-1625 support the segment substrate at a suitable distance from the conductive back plate 1600, typically about 25-200 μm (for example, 100 μm). After the epoxy cures the assembly can be removed from the fixture, and portions of the segment substrate broken away as discussed above. The pins used to space the segment substrate also define holes in the epoxy through which electrical connections (such as pogo pins or others) can contact detector segments. The assembly can be aligned with a CPB optical system using the holes 1602, 1604.

### Representative Control and Calculation Environment

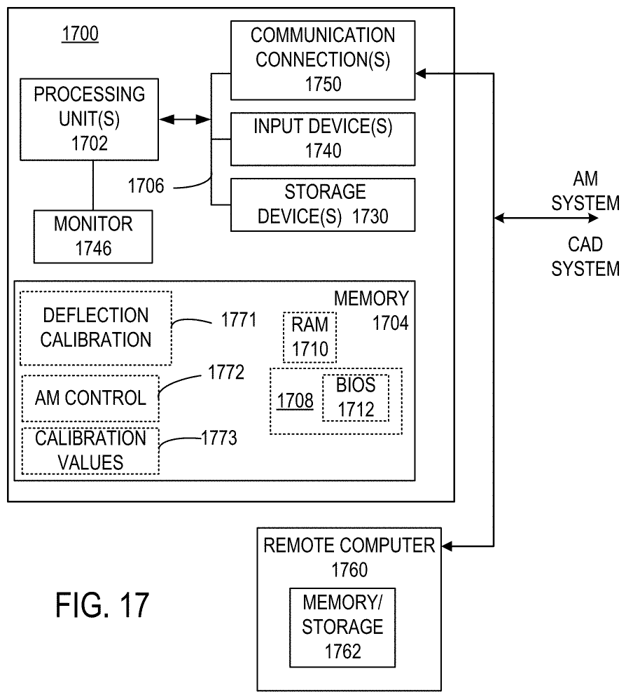

FIG. 17 and the following discussion are intended to provide a brief, general description of an exemplary computing environment in which the disclosed technology may be implemented. Although not required, the disclosed technology is described in the general context of computer-executable instructions, such as program modules, being executed by a personal computer (PC). Generally, program modules include routines, programs, objects, components, data structures, etc., that perform particular tasks or implement particular abstract data types. Moreover, the disclosed technology may be implemented with other computer system configurations, including hand-held devices, multiprocessor systems, microprocessor-based or programmable consumer electronics, network PCs, minicomputers, mainframe computers, application specific integrated circuits (ASICs), field-programmable gate arrays (FPGAs), programmable logic devices (PLDs), systems on a chip (SOCs), and the like. The disclosed technology may also be practiced in distributed computing environments where tasks are performed by remote processing devices that are linked through a communications network. In a distributed computing environment, program modules may be located in both local and remote memory storage devices.

With reference to FIG. 17, an exemplary system for implementing the disclosed technology includes a computing device in the form of an exemplary conventional PC 1700, including one or more processing units 1702, a system memory 1704, and a system bus 1706 that couples various system components including the system memory 1704 to the one or more processing units 1702. The system bus 1706 may be any of several types of bus structures including a memory bus or memory controller, a peripheral bus, and a local bus using any of a variety of bus architectures. The exemplary system memory 1704 includes read only memory (ROM) 1708 and random-access memory (RAM) 1710. A basic input/output system (BIOS) 1712, containing the basic routines that help with the transfer of information between elements within the PC 1700, is stored in ROM 1708. The memory 1704 also contains portions 1771-1773 that include computer-executable instructions and data beam deflection calibration, characterization, and control, additive manufacturing control, and storage of compensation or calibration values.

The exemplary PC 1700 further includes one or more storage devices 1730 such as a hard disk drive for reading from and writing to a hard disk, a magnetic disk drive for reading from or writing to a removable magnetic disk, and an optical disk drive for reading from or writing to a removable optical disk (such as a CD-ROM or other optical media). Such storage devices can be connected to the system bus 1706 by a hard disk drive interface, a magnetic disk drive interface, and an optical drive interface, respectively. The drives and their associated computer-readable media provide nonvolatile storage of computer-readable instructions, data structures, program modules, and other data for the PC 1700. Other types of computer-readable media which can store data that is accessible by a PC, such as magnetic cassettes, flash memory cards, digital video disks, CDs, DVDs, RAMs, ROMs, and the like, may also be used in the exemplary operating environment.

A number of program modules may be stored in the storage devices 1730 including an operating system, one or more application programs, other program modules, and program data. A user may enter commands and information into the PC 1700 through one or more input devices 1740 such as a keyboard and a pointing device such as a mouse. Other input devices may include a digital camera, microphone, joystick, game pad, satellite dish, scanner, or the like. These and other input devices are often connected to the one or more processing units 1702 through a serial port interface that is coupled to the system bus 1706 but may be connected by other interfaces such as a parallel port, game port, or universal serial bus (USB). A monitor 1746 or other type of display device is also connected to the system bus 1706 via an interface, such as a video adapter. Other peripheral output devices, such as speakers and printers (not shown), may be included.

The PC 1700 may operate in a networked environment using logical connections to one or more remote computers, such as a remote computer 1760. In some examples, one or more network or communication connections 1750 are included. The remote computer 1760 may be another PC, a server, a router, a network PC, or a peer device or other common network node, and typically includes many or all of the elements described above relative to the PC 1700, although only a memory storage device 1762 has been illustrated in FIG. 17. The personal computer 1700 and/or the remote computer 1760 can be connected to a logical a local area network (LAN) and a wide area network (WAN). Such networking environments are commonplace in offices, enterprise-wide computer networks, intranets, and the Internet.

When used in a LAN networking environment, the PC 1700 is connected to the LAN through a network interface. When used in a WAN networking environment, the PC 1700 typically includes a modem or other means for establishing communications over the WAN, such as the Internet. In a networked environment, program modules depicted relative to the personal computer 1700, or portions thereof, may be stored in the remote memory storage device or other locations on the LAN or WAN. The network connections shown are exemplary, and other means of establishing a communications link between the computers may be used.

### Representative Manufacturing Methods

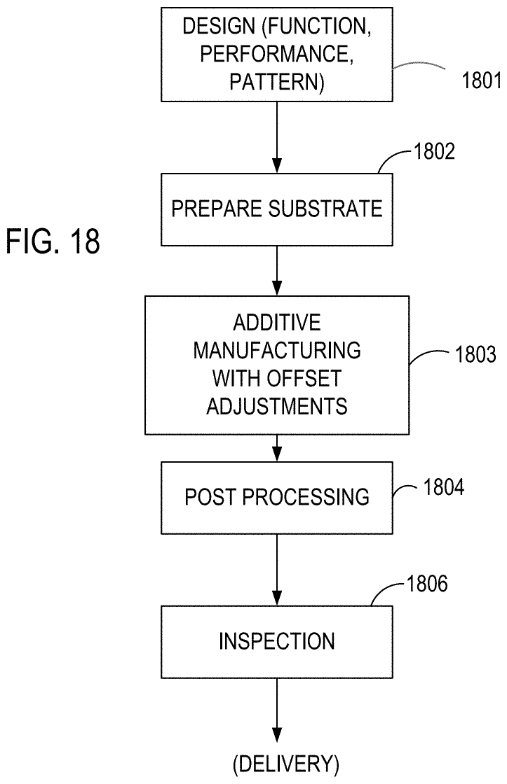

Referring to FIG. 18, a representative method 1800 includes selecting or producing a suitable part design at 1801 and preparing a substrate at 1802. At 1803, additive manufacturing is used to fabricate a part according to the design using compensated electron beam deflections. Based on part specifications, nominal beam deflection values are adjusted by the methods and apparatus described above and the resulting compensated deflection commands are used as the compensated scan values. At 1804, the manufactured part is post processed as needed such as, for example, to polish or smooth surface or remove excess material added by the manufacturing process. At 1806, the part is inspected prior to delivery.

### REPRESENTATIVE EXAMPLES

Example 1 is an electron beam system, including: a Faraday cup; an aperture plate; and a control system operable to compute at least one of position, size, profile, and shape of an electron beam directed to the Faraday cup through the aperture plate based upon a current from the Faraday cup.

Example 2 includes the subject matter of Example 1, and further specifies that the control system is operable to compute at least one of position, size, profile, and shape of the electron beam based upon current from the Faraday cup and the aperture plate.

Example 3 includes the subject matter of any of Examples 1-2, and further includes a current detector connected to the Faraday cup and the aperture plate, the current detector coupled to provide an indication of a detected current to the control system.

Example 4 includes the subject matter of any of Examples 1-3, and further includes an actuator system configured to move the aperture plate relative to the Faraday cup.

Example 5 includes the subject matter of any of Examples 1-4, and further includes a position measurement system configured to measure a position of the aperture plate.

Example 6 includes the subject matter of any of Examples 1-5, and further specifies that the position measurement system includes at least one encoder.

Example 7 includes the subject matter of any of Examples 1-6 and further specifies that the actuator system includes a piezoelectric actuator or a linear motor.

Example 8 includes the subject matter of any of Examples 1-7, and further includes a charge detector situated to receive a backscattered portion of the electron beam, wherein the control system operable to compute at least one of position, size, profile, and shape of the electron beam directed to the Faraday cup based upon a current at the charge detector.

Example 9 includes the subject matter of any of Examples 1-8, and further specifies that the actuator system is operable repetitively, periodically, or randomly translate the aperture plate with respect to the electron beam to variably attenuate the electron beam, and the control system operable to compute at least one of position, size, profile, and shape of an electron beam based on the variable attenuation.

Example 10 includes the subject matter of any of Examples 1-9, and further includes an electron beam deflector coupled to the control system and operable to selectively direct the electron beam to a target based on at least one of the computed position, size, profile, or shape of the electron beam.

Example 11 includes the subject matter of any of Examples 1-10, and further specifies that the electron beam system is an exposure apparatus, a 3D printer, or an SEM.

Example 12 is a method, including: directing an electron beam to an aperture plate; receiving at least a portion of the electron beam at a Faraday cup; and computing at least one of a position, size, profile, and shape of the electron beam based on a current associated with an electron beam portion transmitted to the Faraday cup through an aperture defined in the aperture plate based on the current and a location of the aperture.

Example 13 includes the subject matter of Example 12, and further includes directing the electron beam to a target based on the computed position, size, profile, or shape of the electron beam.

Example 14 includes the subject matter of any of Examples 12-13, and further includes repetitively, periodically, or randomly translating the aperture with respect to the electron beam, wherein the computed position, size, profile, or shape of the electron beam it based on a corresponding repetitive, periodic or random modulation of the current transmitted to the Faraday cup.

Example 15 includes the subject matter of any of Examples 12-14, and further includes detecting a backscattered portion of the electron beam and computing the at least one of the position, size, profile, and shape of the electron beam based upon the detected backscattered portion.

Example 16 includes the subject matter of any of Examples 12-25, and further includes determining electron beam deflection values based on the at least one of the computed position, size, profile, or shape of the electron beam.

Example 17 includes the subject matter of any of Examples 12-16, and further specifies that the aperture plate defines a plurality of apertures, wherein the least one of the position, size, profile, and shape of the electron beam is computed based on a current associated with electron beam portion transmitted to the Faraday cup through each of the plurality of apertures.

Example 18 is an additive manufacturing system, including: a charged-particle-beam (CPB) source operable to direct a CPB to a deposit layer material at a work surface; a sensor exchangably situated at the work surface to receive radiation responsive to the CPB as directed toward the layer material; and a CPB controller coupled to the CPB source and the sensor and operable to adjust at least one characteristic of the CPB based on the received radiation.

Example 19 includes the subject matter of Example 18, and further specifies that the sensor comprises a charged-particle-beam (CPB) trap; a conductive layer containing a plurality of apertures; and an insulator layer fixed between the conductive layer and the CPB trap, the insulator layer having at least one aperture corresponding to the plurality of apertures, wherein the CPB controller is operable to adjust the CPB based on a portion of the CPB received by the CPB trap.

Example 20 includes the subject matter of Example 19, and further specifies that the insulator layer is a ring-shaped insulator layer having a central aperture, wherein the central aperture has a diameter such that each of the plurality of apertures permits transmission of the CPB to the CPB trap through the plurality of apertures of the conductive layer and the central aperture of the insulator layer.

Example 21 includes the subject matter of any of Examples 18-20, and further specifies that the at least one aperture of the insulator layer is recessed with respect to each of the plurality of apertures in the conductive layer.

Example 22 includes the subject matter of any of Examples 18-21, and further specifies that the insulator layer includes a plurality of apertures each corresponding to a respective aperture in the conductive layer.

Example 23 includes the subject matter of any of Examples 18-22, and further specifies that each of the plurality of apertures of the insulator layer tapers so as to widen from an outer surface adjacent an interior surface of the conductive layer surface to the CPB trap.

Example 24 includes the subject matter of any of Examples 18-23, and further specifies that the apertures of the insulator layer and the conductive layer have frustoconical tapers.

Example 25 includes the subject matter of any of Examples 18-24, and further specifies that the apertures in the conductive layer are arranged in a rectangular array.

Example 26 includes the subject matter of any of Examples 18-25, and further specifies that the CPB controller is operable to establish CPB deflections based on locations of the plurality of apertures.

Example 27 includes the subject matter of any of Examples 18-26, and further specifies that the sensor comprises: an aperture plate defining a beam sensing aperture that is transmissive to the CPB, where the CPB controller is coupled to the sensor to receive a signal associated with a periodic attenuation of the CPB by the beam sensing aperture, and, based on the received signal, provide an estimate of at least one of CPB position, size, and shape at the aperture plate in at least one dimension.

Example 28 includes the subject matter of any of Examples 18-27, and further specifies that the signal associated with the periodic attenuation is based one or more portions of the CPB transmitted, reflected, or scattered by the aperture plate or secondary emission responsive to the portions of the CPB transmitted, reflected, or scattered by the aperture plate.

Example 29 includes the subject matter of any of Examples 18-27, and further specifies that the sensor includes: at least one actuator coupled to the beam sensing aperture; and an actuator driver coupled to the at least one actuator and operable to oscillate the aperture plate to periodically attenuate the CPB with the beam sensing aperture, wherein the CPB controller is situated to receive the signal associated with the periodic attenuation of the CPB by the beam sensing aperture, and, based on the received signal and the oscillation of the aperture plate, provide the estimate of the CPB position at the aperture plate in at least one dimension.

Example 30 includes the subject matter of any of Examples 18-29, and further specifies that the at least one actuator includes a first piezoelectric actuator and a second piezoelectric actuator operable to oscillate the aperture plate periodically in different directions, and the CPB controller provides the estimate of at least one of the CPB position, size, and shape at the aperture plate in two dimensions.

Example 31 includes the subject matter of any of Examples 18-30, and further specifies that the sensor includes a stage coupled to the beam sensing aperture, wherein the stage is operable to translate the beam sensing aperture to a plurality of beam sampling locations and the actuator driver is coupled to the at least one actuator to oscillate aperture plate to periodically attenuate the CPB at each of the beam sampling locations; and wherein the CPB controller is configured to provide estimates of at least one of the CPB position, size, and shape at each of the beam sampling locations.

Example 32 includes the subject matter of any of Examples 18-31, and further specifies that the CPB controller is coupled to a beam deflector driver to oscillate the CPB at the aperture plate so that the signal associated with the periodic attenuation of the CPB received by the beam sensing aperture is based on CPB attenuation produced by the oscillation of the CPB at the aperture plate, wherein the CPB controller is coupled to receive the signal associated with the periodic attenuation of the CPB by the beam sensing aperture and the oscillation of the CPB, and, based on the received signal and the oscillation of the aperture plate and the CPB, provide the estimate of the CPB position size, or shape at the aperture plate in at least one dimension.

Example 33 includes the subject matter of any of Examples 18-32, and further specifies that the sensor comprises: a conductive plate that defines an aperture that is transmissive to the CPB; at least two electrically isolated conductive segments symmetrically situated about the aperture; and a segmented insulator layer situated between and secured to the conductive plate and the conductive segments.

Example 34 includes the subject matter of any of Examples 18-33, and further specifies that the conductive plate and the segmented insulator layer define contact apertures and further includes electrical contacts situated in each of the contact apertures and electrically connected to a respective conductive segment.

Example 35 includes the subject matter of any of Examples 18-34, and further specifies that the electrical contacts are conductive pins that are retained in respective insulative housings; and elastic members are situated in each of the insulative housings, each elastic member situated to urge the conductive pins into the contact apertures and against the respective conductive segments to make electrical contact.

Example 36 includes the subject matter of any of Examples 18-35, and further specifies that the at least two electrically isolated conductive segments include four quarter circle segments that are electrically isolated, wherein the conductive segments are separated by first and second radially directed and orthogonal gaps along axes that extend through a center of the aperture.

Example 37 includes the subject matter of any of Examples 18-36, and further specifies that the sensor comprises: an image sensor situated to obtain an image of a cathodoluminescence pattern from a target situated at the work surface, wherein the CPB controller is operable to adjust the at least one characteristic of the CPB based on the image of the cathodoluminescence pattern.

Example 38 includes the subject matter of any of Examples 18-37, and further specifies that the target is a patterned target, and the CPB is operable to adjust at least one characteristic of the CPB based on the image of the cathodoluminescence pattern and the target pattern.

Example 39 includes the subject matter of any of Examples 18-38, and further specifies that the target pattern includes a regular array of target locations.

Example 40 is an aperture assembly, including: a charged-particle-beam (CPB) trap; a conductive layer containing a plurality of apertures; and an insulator layer fixed between the conductive layer and the CPB trap, the insulator layer having at least one aperture corresponding to the plurality of apertures.

Example 41 includes the subject matter of Example 40, and further specifies that the insulator layer is a ring-shaped insulator layer having a central aperture, wherein the central aperture has a diameter such that each of the plurality of apertures permits transmission of a CPB to the CPB trap through the plurality of apertures of the conductive layer and the central aperture of the insulator layer.

Example 42 includes the subject matter of any of Examples 40-41, and further specifies that the at least one aperture of the insulator layer is recessed with respect to each of the plurality of apertures in the conductive layer.

Example 43 includes the subject matter of any of Examples 40-42, and further specifies that the insulator layer includes a plurality of apertures each corresponding to a respective aperture in the conductive layer.

Example 44 includes the subject matter of any of Examples 40-43, and further specifies that each of the plurality of apertures of the insulator layer tapers to widen from an outer surface adjacent an interior surface of the conductive layer surface to the CPB trap.

Example 45 includes the subject matter of any of Examples 40-44, and further specifies that the apertures of the insulator layer and the conductive layer have frustoconical tapers.

Example 46 includes the subject matter of any of Examples 40-45, and further specifies that the apertures in the conductive layer are arranged in a rectangular array.

Example 47 is a method, including: sequentially deflecting a charged-particle beam (CPB) about each aperture of a plurality of apertures, each aperture associated with a respective CPB trap, wherein the CPB traps are electrically coupled; measuring current responsive to the sequentially deflected CPB at the electrically coupled CPB traps; and recording deflection values associated with each aperture.

Example 48 includes the subject matter of Example 47, and further specifies that the sequential deflection of the CPB about the aperture is a scan of the CPB.

Example 49 includes the subject matter of any of Examples 47-48, and further specifies that the scan of the CPB is a raster scan.

Example 50 includes the subject matter of any of Examples 47-49, and further specifies that the deflecting the CPB to each aperture comprises directing the CPB to at least one aperture of the plurality of apertures with a first beam focus and then directing the CPB to each aperture with a second beam focus, wherein the deflection values associated with the second beam focus are the recorded deflection values and wherein a beam size at the plurality of apertures is larger with the first beam focus than the second beam focus.

Example 51 includes the subject matter of any of Examples 47-50, and further specifies that the deflecting of the CPB to each aperture is done continuously and the deflection values are obtained by decoding a continuous signal.

Example 52 includes the subject matter of any of Examples 47-51, and further specifies that the deflecting of the CPB to each aperture is done stepwise and the deflection values are obtained at each step.

Example 53 includes the subject matter of any of Examples 47-52, and further includes applying one or more of the recorded deflection values to process a substrate at a selected location with the CPB.

Example 54 includes the subject matter of any of Examples 47-53, and further includes: based on one or more of a reflected CPB current, a transmitted CPB current, a secondary CPB current, or a scattered CPB current associated with each aperture, adjusting CPB deflections to obtain CPB deflection values corresponding to locations of each of the apertures; and recording the adjusted CPB deflection values associated with each aperture.

Example 55 includes the subject matter of any of Examples 47-54, and further includes determining CPB deflection values for locations between the apertures based on the recorded adjusted CPB deflection values.

Example 56 includes the subject matter of any of Examples 47-55, and further specifies that the CPB deflection values for locations between the apertures are based on interpolation with the recorded adjusted CPB deflection values.

Example 57 includes the subject matter of any of Examples 47-56, and further includes: obtaining an image of an aperture plate defining the plurality of apertures, the aperture plate situated at a selected plane; obtaining a cathodoluminescence image by deflecting the CPB to the selected plane based on a plurality of CPB deflection values;

and producing initial CPB deflection values based on the cathodoluminescence image and the image of the aperture plate.

Example 58 includes the subject matter of any of Examples 47-57, and further specifies that the cathodoluminescence image is obtained by deflecting the CPB to aperture plate and recording cathodoluminescence intensity values associated with the cathodoluminescence.

Example 59 is an apparatus, including: an aperture plate defining a beam sensing aperture that is transmissive to a charged particle beam (CPB); and a position analyzer situated to receive a signal associated with a periodic attenuation of the CPB by the beam sensing aperture, and, based on the received signal, provide an estimate of at least one of CPB position, size, and shape at the aperture plate in at least one dimension.

Example 60 includes the subject matter of Example 59, and further specifies that the signal associated with the periodic attenuation is based one or more portions of the CPB transmitted, reflected, or scattered by the aperture plate or secondary emission responsive to the portions of the CPB transmitted, reflected, or scattered by the aperture plate.

Example 61 includes the subject matter of any of Examples 59-60, and further includes: at least one actuator coupled to the beam sensing aperture; and an actuator driver coupled to the at least one actuator and operable to oscillate the aperture plate to periodically attenuate the CPB with the beam sensing aperture, wherein the position analyzer is situated to receive the signal associated with the periodic attenuation of the CPB by the beam sensing aperture, and, based on the received signal and the oscillation of the aperture plate, provide the estimate of the CPB position at the aperture plate in at least one dimension.

Example 62 includes the subject matter of any of Examples 59-61, and further specifies that the at least one actuator includes a first piezoelectric actuator and a second piezoelectric actuator operable to oscillate the aperture plate periodically in different directions, and the position analyzer provides the estimate of at least one of the CPB position, size, and shape at the aperture plate in two dimensions.

Example 63 includes the subject matter of any of Examples 59-62, and further includes: a stage coupled to the beam sensing aperture, wherein the stage is operable to translate the beam sensing aperture to a plurality of beam sampling locations and the actuator driver is coupled to the at least one actuator to oscillate the beam sensing aperture plate to periodically attenuate the CPB at each of the beam sampling locations;

and the position analyzer is configured to provide estimates of at least one of the CPB position, size, and shape at each of the beam sampling locations.

Example 64 includes the subject matter of any of Examples 59-63, and further includes a beam deflector driver operable to oscillate the CPB at the beam sensing aperture plate so that the signal associated with the periodic attenuation of the CPB received by the beam sensing aperture is based on CPB attenuation produced by the oscillation of the CPB at the beam sensing aperture plate, wherein the position analyzer is situated to receive the signal associated with the periodic attenuation of the CPB by the beam sensing aperture and the oscillation of the CPB, and, based on the received signal and the oscillation of the aperture plate and the CPB, provide the estimate of the CPB position size, or shape at the aperture plate in at least one dimension.

Example 65 includes the subject matter of any of Examples 59-64, and further includes a beam deflector driver operable to oscillate the CPB at the beam sensing aperture plate so that the signal associated with the periodic attenuation of the CPB received by the beam sensing aperture is based on CPB attenuation produced by the oscillation of the CPB at the beam sensing aperture plate.

Example 66 is a method of measuring CPB position, size, or shape, including: producing a periodic attenuation of a CPB with a beam sensing aperture; and measuring a periodic current responsive to the CPB attenuation, the periodic current associated with one or more of a transmitted, reflected, or absorbed CPB portion, or secondary emission responsive to one or more such beam portions; and based on the measured periodic current, determining CPB location with respect to the beam sensing aperture.

Example 67 includes the subject matter of Example 66, and further specifies that the periodic attenuation includes periodic attenuations in two dimensions in directions perpendicular to a CPB propagation axis and the CPB location with respect to the beam sensing aperture is determined in the two dimensions.

Example 68 includes the subject matter of any of Examples 66-67, and further specifies that the periodic attenuation includes periodic attenuations associated with a first frequency and a second frequency that is different from the first frequency, and the CPB location with respect to the beam sensing aperture is determined in a first direction and a second direction based on the first frequency and the second frequency, respectively.

Example 69 includes the subject matter of any of Examples 66-68, and further specifies that the measured periodic current is processed to obtain a component at a frequency of the periodic attenuation and the CPB location with respect to the beam sensing aperture is determined based on the component.

Example 70 is a CPB detector, including: a conductive plate that defines an aperture that is transmissive to a CPB; at least two electrically isolated conductive segments symmetrically situated about the aperture; and a segmented insulator layer situated between and secured to the conductive plate and the conductive segments.

Example 71 includes the subject matter of any Example 70, and further specifies that the conductive plate and the segmented insulator layer define contact apertures and further includes electrical contacts situated in each of the contact apertures and electrically connected to a respective conductive segment.

Example 72 includes the subject matter of any of Examples 70-71, and further specifies that the electrical contacts are conductive pins that are retained in respective insulative housings; and elastic members are situated in each of the insulative housings, each elastic member situated to urge the conductive pins into the contact apertures and against the respective conductive segments to make electrical contact.

Example 73 includes the subject matter of any of Examples 70-72, and further specifies that the at least two electrically isolated conductive segments include four quarter circle segments that are electrically isolated, wherein the conductive segments are separated by first and second radially directed and orthogonal gaps along axes that extend through a center of the aperture.

Example 74 is a method, including: directing a CPB to a CPB detector having a plurality of electrically isolated conductive segments that are distributed in a plane and azimuthally about an axis that is perpendicular to a CPB transmissive aperture; and determining a CPB position, shape, or size at the CPB detector based on current differences between at least a first group of segments and a second group of segments, wherein the first group of segments is different from the second group of segments.

Example 75 includes the subject matter of Example 74, and further specifies that each of the conductive segments has a common radius.

Example 76 includes the subject matter of any of Examples 74-75, and further specifies that the plurality of conductive segments consists of four quarter circular electrically isolated conductive segments, wherein each of the conductive segments has a common radius; and the determining a CPB position, shape, or size at the CPB detector is based on current differences between first, second, third, and fourth groups of segments, wherein the first group consists of a first pair of the segments the second group consists of a second pair of the segments, the third group of segments consists of a third pair of the segments and the fourth group of the segments consists of a fourth pair of the segments, wherein each of the first, second, thirds, and fourth pairs of segments is different.

Example 77 includes the subject matter of any of Examples 74-76, and further specifies that the first pair of the segments is electrically isolated from the second pair of the segments by a linear gap that extends between the first pair of segments and the second pair of segments.

Example 78 includes the subject matter of any of Examples 74-77, and further includes directing the CPB through a CPB transmissive aperture situated on the axis, wherein each of the conductive segments terminates at the CPB transmissive aperture.

In view of the many possible embodiments to which the principles of the disclosure may be applied, it should be recognized that the illustrated embodiments are only preferred examples and should not be taken as limiting the scope of the disclosure.

We claim:

1. An apparatus, comprising:
an aperture plate defining a beam sensing aperture that is transmissive to a charged particle beam (CPB); and
a position analyzer situated to receive a signal associated with a periodic attenuation of the CPB by the beam sensing aperture, and, based on the received signal, provide an estimate of at least one of a CPB position, size, and shape at the aperture plate in at least one dimension.

2. The apparatus of claim 1, wherein the signal associated with the periodic attenuation is based one or more portions of the CPB transmitted, reflected, or scattered by the aperture plate or secondary emission responsive to the portions of the CPB transmitted, reflected, or scattered by the aperture plate.

3. The apparatus of claim 2, further comprising:
at least one actuator coupled to the beam sensing aperture; and
an actuator driver coupled to the at least one actuator and operable to oscillate the aperture plate to periodically attenuate the CPB with the beam sensing aperture, wherein the position analyzer is situated to receive the signal associated with the periodic attenuation of the CPB by the beam sensing aperture, and, based on the received signal and the oscillation of the aperture plate, provide the estimate of the CPB position at the aperture plate in at least one dimension.

4. The apparatus of claim 3, wherein the at least one actuator includes a first piezoelectric actuator and a second piezoelectric actuator operable to oscillate the aperture plate periodically in different directions, and the position analyzer provides the estimate of at least one of the CPB position, size, and shape at the aperture plate in two dimensions.

5. The apparatus of claim 3, further comprising:
a stage coupled to the beam sensing aperture, wherein the stage is operable to translate the beam sensing aperture to a plurality of beam sampling locations and the actuator driver is coupled to the at least one actuator to oscillate the beam sensing aperture to periodically attenuate the CPB at each of the beam sampling locations; and
the position analyzer is configured to provide estimates of at least one of the CPB position, size, and shape at each of the beam sampling locations.

6. The apparatus of claim 3, further comprising a beam deflector driver operable to oscillate the CPB at the aperture plate defining the beam sensing aperture so that the signal associated with the periodic attenuation of the CPB received by the beam sensing aperture is based on CPB attenuation produced by the oscillation of the CPB at the aperture plate, wherein the position analyzer is situated to receive the signal associated with the periodic attenuation of the CPB by the beam sensing aperture and the oscillation of the CPB, and, based on the received signal and the oscillation of the aperture plate and the CPB, provide the estimate of the CPB position, size, or shape at the aperture plate in at least one dimension.

7. The apparatus of claim 1, further comprising a beam deflector driver operable to oscillate the CPB at the aperture plate so that the signal associated with the periodic attenuation of the CPB received by the aperture plate is based on CPB attenuation produced by the oscillation of the CPB at the aperture plate.

8. A method of measuring CPB position, size, or shape, comprising:
producing a periodic attenuation of a CPB with a beam sensing aperture; and
measuring a periodic current responsive to the CPB attenuation, the periodic current associated with one or more of a transmitted, reflected, or absorbed CPB portion, or secondary emission responsive to one or more such beam portions; and
based on the measured periodic current, determining CPB location with respect to the beam sensing aperture.

9. The method of claim 8, wherein the periodic attenuation includes periodic attenuations in two dimensions in directions perpendicular to a CPB propagation axis and the CPB location with respect to the beam sensing aperture is determined in the two dimensions.

10. The method of claim 9, wherein the periodic attenuation includes periodic attenuations associated with a first frequency and a second frequency that is different from the first frequency, and the CPB location with respect to the beam sensing aperture is determined in a first direction and a second direction based on the first frequency and the second frequency, respectively.

11. The method of claim 8, wherein the measured periodic current is processed to obtain a component at a frequency of the periodic attenuation and the CPB location with respect to the beam sensing aperture is determined based on the component.

12. A CPB detector, comprising:
a conductive plate that defines an aperture that is transmissive to a CPB;
at least two electrically isolated conductive segments symmetrically situated about the aperture; and
a segmented insulator layer situated between and secured to the conductive plate and the at least two electrically isolated conductive segments.

13. The CPB detector of claim 12, wherein the conductive plate and the segmented insulator layer define contact apertures and further comprising electrical contacts situated in each of the contact apertures and electrically connected to a respective conductive segment.

14. The CPB detector of claim 13, wherein the electrical contacts are conductive pins that are retained in respective insulative housings; and
elastic members are situated in each of the respective insulative housings, each elastic member situated to urge the conductive pins into the contact apertures and against respective conductive segments to make electrical contact.

15. The CPB detector of claim 14, wherein the at least two electrically isolated conductive segments include four quarter circle segments that are electrically isolated, wherein the conductive segments are separated by first and second radially directed and orthogonal gaps along axes that extend through a center of the aperture.
